(19) United States
(12) Patent Application Publication
(10) Pub. No.: US 2012/0268089 A1
(43) Pub. Date: Oct. 25, 2012

(54) LEVEL SHIFTER, CONTROLLER, AND DC-TO-DC CONVERTER

(75) Inventor: Kei KASAI, Tokyo (JP)

(73) Assignee: KABUSHIKI KAISHA TOSHIBA, Tokyo (JP)

(21) Appl. No.: 13/420,655

(22) Filed: Mar. 15, 2012

(30) Foreign Application Priority Data
Apr. 22, 2011 (JP) 2011-096214

(51) Int. Cl. G05F 1/46; H03L 5/00

(52) U.S. Cl. 323/271; 327/333

(57) ABSTRACT

According to one embodiment, a level shifter includes a current generator, a current switch, and a protection circuit. The current generator is connected between a first high potential terminal and a first low potential terminal and configured to generate a first current at a first output line. The current switch is connected between a second high potential terminal and a second low potential terminal. The current switch is configured to receive the first current with a higher current supply capacity than the current generator and pass the first current or cut off the first current in accordance with an input signal. The protection circuit is connected to the first output line between the current generator and the current switch. The protection circuit is configured to limit an electric potential of the first output line.

### CROSS-REFERENCE TO RELATED APPLICATIONS

This application is based upon and claims the benefit of priority from Japanese Patent Application No. 2011-096214, filed on Apr. 22, 2011; the entire contents of which are incorporated herein by reference.

### FIELD

Embodiments described herein relate generally to a level shifter, a controller, and a DC-to-DC converter.

### BACKGROUND

Lowering the voltage of integrated circuits such as CPUs has been advanced in response to the requirements of decreasing the power consumption of apparatuses and raising the functionality thereof. On the other hand, in conventionally used systems and systems using analog signals or the like, a high voltage may be required. Thus, in the case where systems that operate with different power supply voltages coexist, a level shifter is used in order to transmit signals between the systems. For example, in a DC-DC converter, a control signal produced in a low breakdown voltage unit, such as a controller, is transmitted to a high breakdown voltage unit, such as a switch element, using the level shifter. A quick response is required for the level shifter in accordance with the downsizing and speeding-up of the DC-DC converter.

### BRIEF DESCRIPTION OF THE DRAWINGS

FIG. 1 is a circuit diagram illustrating a configuration of a level shifter according to a first embodiment;

FIGS. 2A and 2B are waveform diagrams of main signals of the level shifter;

FIGS. 3A and 3B are other waveform diagrams of main signals of the level shifter;

FIG. 4 is a circuit diagram illustrating another configuration of a level shifter according to the first embodiment;

FIG. 5 is a circuit diagram illustrating another configuration of a level shifter according to the first embodiment;

FIG. 6 is a circuit diagram illustrating another configuration of a level shifter according to the first embodiment;

FIG. 7 is a circuit diagram illustrating a configuration of a level shifter according to a second embodiment;

FIGS. 8A to 8C are waveform diagrams of main signals of the level shifter;

FIGS. 9A to 9C are other waveform diagrams of the main signals of the level shifter;

FIG. 10 is a circuit diagram illustrating a configuration of a level shifter according to a third embodiment;

FIGS. 11A to 11F are waveform diagrams of main signals of the level shifter;

FIGS. 12A to 12F are other waveform diagrams of main signals of the level shifter;

FIG. 13 is a circuit diagram illustrating a configuration of a DC-DC converter including a controller according to a fourth embodiment;

FIGS. 14A to 14E are waveform diagrams of main signals of the DC-DC converter;

FIG. 15 is a circuit diagram of a level shifter of a first comparative example;

FIGS. 16A and 16B are waveform diagrams of main signals of the level shifter shown in FIG. 15;

FIGS. 17A and 17B are other waveform diagrams of the main signals of the level shifter shown in FIG. 15;

FIG. 18 is a circuit diagram of a level shifter of a second comparative example;

FIGS. 19A and 19B are waveform diagrams of main signals of the level shifter shown in FIG. 18; and

FIGS. 20A and 20B are other waveform diagrams of the main signals of the level shifter shown in FIG. 18.

### DETAILED DESCRIPTION

In general, according to one embodiment, a level shifter includes a current generator, a current switch, and a protection circuit. The current generator is connected between a first high potential terminal and a first low potential terminal and configured to generate a first current at a first output line. The current switch is connected between a second high potential terminal and a second low potential terminal. The current switch is configured to receive the first current with a higher current supply capacity than the current generator and pass the first current or cut off the first current in accordance with an input signal. The protection circuit is connected to the first output line between the current generator and the current switch. The protection circuit is configured to limit an electric potential of the first output line to not less than an electric potential of the first low potential terminal and not more than an electric potential of the first high potential terminal.

Hereinbelow, embodiments of the invention are described in detail with reference to the drawings. In the specification of this application and the drawings, components similar to those described in regard to a drawing thereinabove are marked with the same reference numerals, and a detailed description is omitted as appropriate.

### First Embodiment

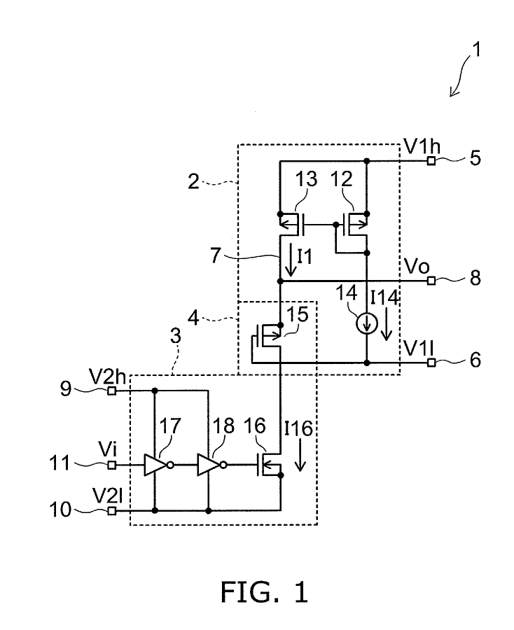

FIG. 1 is a circuit diagram illustrating a configuration of a level shifter according to a first embodiment.

As shown in FIG. 1, a level shifter 1 includes a current generator 2, a current switch 3, and a protection circuit 4.

The current generator 2 is connected between a first high potential terminal 5 and a first low potential terminal 6, and generates a first current I1 and outputs it to a first output line 7. Here, the first current I1 has a current value such that a transistor turns ON to operate. An output terminal 8 is connected to the first output line 7. The electric potential of an output signal Vo produced at the output terminal 8 is equal to the electric potential of the first output line 7.

The current switch 3 is connected between a second high potential terminal 9 and a second low potential terminal 10, and receives the first current I1 with a larger current supply capacity than the current generator 2. An input signal Vi is inputted to the current switch 3 via an input terminal 11. Here, the input signal Vi is a digital signal in which the electric potential changes into L or H between the electric potential V2h of the second high potential terminal 9 and the electric potential V2l of the second low potential terminal 10. Here, L and H are electric potentials at which the electric potential of the input signal Vi becomes the logic value 0 (false) and the logic value 1 (true), respectively.

The current switch 3 passes the first current I1 or cuts off the first current I1 in accordance with the input signal Vi. As mentioned above, the current switch 3 has a larger current supply capacity than the current generator 2, and the current supply capacity of the current switch 3 is larger than the current value of the first current I1. Therefore, the electric potential of the first output line 7, that is, the electric potential of the output signal Vo produced at the output terminal 8 becomes a low level or a high level higher than the low level. Herein, the low level and the high level are electric potentials at which the electric potential of the output signal Vo becomes the logic value 0 (false) and the logic value 1 (true), respectively.

The protection circuit 4 is connected to the first output line 7 between the current generator 2 and the current switch 3. The protection circuit 4 limits the electric potential of the first output line 7 to not less than the electric potential V1l of the first low potential terminal 6 and not more than the electric potential V1h of the first high potential terminal 5. Therefore, the low level mentioned above is limited to not less than the electric potential V1l of the first low potential terminal 6, and the high level is limited to not more than the electric potential V1h of the first high potential terminal 5.

The voltage applied to the current generator 2 is limited to the potential difference V1h−V1l between the electric potential V1h of the first high potential terminal 5 and the electric potential V1l of the first low potential terminal 6. The protection circuit 4 protects the current generator 2 from overvoltage.

Thus, the current generator 2 is a high side block that operates using the electric potential V1h of the first high potential terminal 5 as a reference. Furthermore, the current switch 3 is a low side block that operates using the electric potential V2l of the second low potential terminal 10 as a reference. The second low potential terminal 10 may be connected to, for example, the ground. The electric potential V1h of the first high potential terminal 5 is set not less than the electric potential V2h of the second high potential terminal 9. A voltage not less than the power supply voltage V2h−V2l of the low side block is supplied between the first high potential terminal 5 and the second low potential terminal 10.

The level shifter 1 level-shifts the input signal Vi with the logic amplitude V2h−V2l of the low side block, and produces the output signal Vo with the logic amplitude V1h−V1l of the high side block.

Next, the components are described in detail.

In the current generator 2, a P-channel MOSFET (hereinafter PMOS) 12 and a constant current source 14 are connected in series between the first high potential terminal 5 and the first low potential terminal 6. The source of the PMOS 12 is connected to the first high potential terminal 5, and the gate and the drain are connected to the constant current source 14. The constant current source 14 is connected between the PMOS 12 and the first low potential terminal 6, and generates a constant current I14. The constant current I14 flows through the PMOS 12.

A PMOS 13 is connected between the first high potential terminal 5 and the first output line 7. The source of the PMOS 13 is connected to the first high potential terminal 5, and the drain is connected to the first output line 7. The gate of the PMOS 13 is connected to the gate and the drain of the PMOS 12. The PMOS 13 constitutes a current mirror using the PMOS 12 as the reference side. The constant current I14 generated in the constant current source 14 is turned back at the current mirror. The first current I1 is outputted to the first output line 7.

When the size ratio of the PMOS 13 and the PMOS 12 is denoted by W13/W12, the first current I1 is expressed by Formula (1).

I1=I14×(W13/W12) (1)

In the current switch 3, an N-channel MOSFET (hereinafter NMOS) 16 is connected between the protection circuit 4 and the second low potential terminal 10. The NMOS 16 receives the first current I1 that the current generator 2 has generated via the protection circuit 4. The drain of the NMOS 16 is connected to the first output line 7 via the protection circuit 4. The source of the NMOS 16 is connected to the second low potential terminal 10. The input signal Vi is inputted to the gate of the NMOS 16 from the input terminal 11 via inverter circuits (INVs) 17 and 18.

The INVs 17 and 18 are connected between the second high potential terminal 9 and the second low potential terminal 10. The electric potential V2h of the second high potential terminal 9 and the electric potential V2l of the second low potential terminal 10 are supplied to the INVs 17 and 18. The INVs 17 and 18 operate using the electric potential V2l of the second low potential terminal 10 as a reference. The input signal Vi is inputted to the INV 17 from the input terminal 11.

As mentioned above, the input signal Vi is a digital signal in which the electric potential changes between the electric potential V2h of the second high potential terminal 9 and the electric potential V2l of the second low potential terminal 10. The INVs 17 and 18 invert the input signal Vi twice, and outputs a signal in phase with the input signal Vi. The INVs 17 and 18 are interposed in order to obtain an interface between the input signal Vi and the gate-source voltage of the NMOS 16. The INV 17 or the INV 18 may be omitted depending on the logic of the output signal Vo with respect to the logic of the input signal Vi.

The NMOS 16 turns ON or OFF in accordance with the electric potential of the input signal Vi.

When the electric potential of the input signal Vi is H that is higher than the logic threshold voltage of the INV 17, the NMOS 16 turns ON. The first current I1 flows through the output line 7.

The current supply capacity of the NMOS 16 is expressed by Formula (2), where the current flowing when the NMOS 16 turns ON is denoted by I16.

I16=(βn/2)×(Vgs16−Vtn)² (2)

where βn is a constant determined by the structure, such as the configuration, of the NMOS 16, Vgs16 is the gate-source voltage of the NMOS 16, and Vtn is the threshold voltage.

The current value of the current I16 corresponding to the current supply capacity of the NMOS 16 is set larger than the current value of the first current I1. Therefore, the electric potential of the first output line 7, that is, the electric potential of the output signal Vo produced at the output terminal 8 becomes the low level. The low level is almost equal to the electric potential V1l of the first low potential terminal 6 due to the protection circuit 4.

When the electric potential of the input signal Vi is L that is lower than the logic threshold voltage of the INV 17, the NMOS 16 turns OFF. The first current I1 is cut off. The electric potential of the first output line 7, that is, the electric potential of the output signal Vo produced at the output terminal 8 becomes the high level higher than the low level. The high level is almost equal to the electric potential V1h of the first high potential terminal 5.

In the protection circuit 4, a PMOS 15 is connected to the first output line 7 between the PMOS 13 of the current generator 2 and the NMOS 16 of the current switch 3. The source of the PMOS 15 is connected to the first output line 7, and connected to the drain of the PMOS 13 via the first output line 7. The drain of the PMOS 15 is connected to the drain of the NMOS 16. The gate of the PMOS 15 is connected to the first low potential terminal 6.

When the NMOS 16 turns ON, the PMOS 15 turns ON and the first current I1 flows through the first output line 7. At this time, the electric potential of the first output line 7 is limited to an electric potential higher than the electric potential V1l of the first low potential terminal 6 by an amount of the inter-source/gate voltage Vsg15 of the PMOS 15 (lower by an amount of the gate-source voltage Vgs 15).

When the NMOS 16 turns OFF, the PMOS 15 turns OFF and the first current I1 of the first output line 7 is cut off. At this time, the electric potential of the first output line 7 is drawn by the PMOS 13 that attempts to flow the first current I1, and becomes the electric potential V1h of the first high potential terminal 5.

Thus, the protection circuit 4 limits the electric potential of the first output line 7 to not less than the electric potential V1l of the first low potential terminal 6 and not more than the electric potential V1h of the first high potential terminal 5. Therefore, the voltage applied to the current generator 2 is limited within the potential difference V1h−V1l, and the current generator 2 is protected from overvoltage.

Next, the operation of the level shifter 1 is described with reference to waveform diagrams.

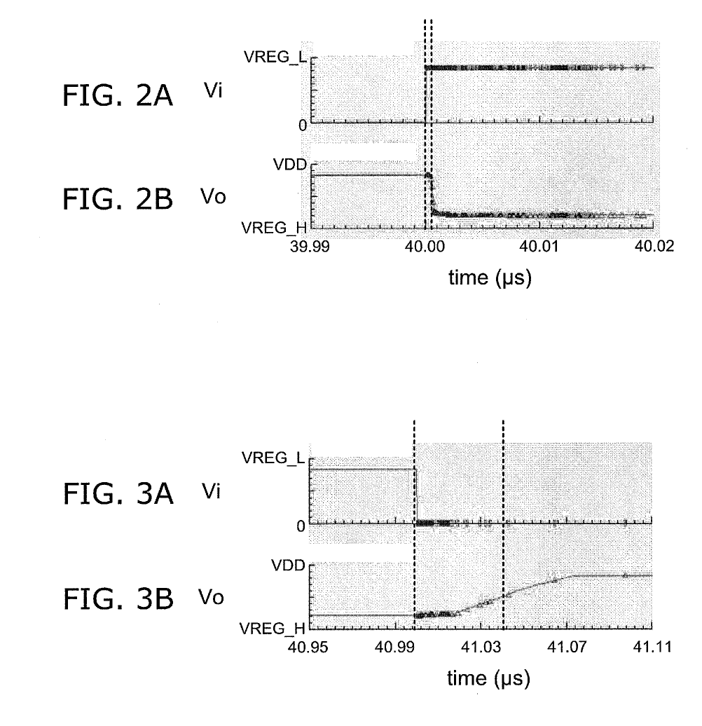

FIGS. 2A and 2B are waveform diagrams of main signals of the level shifter, where FIG. 2A shows the input signal Vi, and FIG. 2B shows the output signal Vo.

FIGS. 3A and 3B are other waveform diagrams of the main signals of the level shifter, where FIG. 3A shows the input signal Vi, and FIG. 3B shows the output signal Vo.

FIGS. 2A and 2B and FIGS. 3A and 3B take the time (time) on the horizontal axis and the electric potential on the vertical axis, and show the simulation results of the output signal Vo when the electric potential of the input signal Vi of the level shifter 1 increases and when it decreases.

It is assumed that the electric potential V2h of the second high potential terminal 9 equals VREG_L, the electric potential V2l of the second low potential terminal 10 equals 0 V, the electric potential V1h of the first high potential terminal 5 equals VDD, and the electric potential V1l of the first low potential terminal 6 equals VREG_H. Therefore, the L and the H of the electric potential of the input signal Vi are almost 0 V and VREG_L, respectively, and the low level and the high level of the output signal Vo are almost VREG_H and VDD, respectively.

Furthermore, it is assumed that the constant current I14 of the constant current source 14 equals 10 μA, and the size ratio W13/W12 of the PMOS 13 and the PMOS 12 equals 8. From Formula (1), the first current I1 equals 80 μA. The current I16 of the NMOS 16 is set to I16>IL

The electric potential of the input signal Vi increases from 0 V to VREG_L at time equals 40.00 μs (FIG. 2A). When the electric potential of the input signal Vi increases to H, the NMOS 16 turns ON. The first current I1 flows. The current value of the current I16 corresponding to the current supply capacity of the NMOS 16 is set larger than the current value of the first current IL Consequently, when the NMOS 16 changes from OFF to ON, the first current I1 flows through the NMOS 16, and a charge stored in a parasitic capacitance etc. is drawn into the NMOS 16 from the output terminal 8.

The electric potential of the output signal Vo produced at the output terminal 8 becomes the low level (FIG. 2B). The low level is almost equal to the electric potential V1l equals VREG_H of the first low potential terminal 6 due to the protection circuit 4. The propagation delay time in the direction in which the electric potential of the output signal Vo changes from the high level to the low level is approximately 0.7 ns.

Therefore, the electric potential of the output signal Vo decreases rapidly from the high level to the low level as compared to the case where the first current I1 of a constant current flows through the current switch 3. When the electric potential of the output signal Vo has become the steady state of the low level, the current flowing through the NMOS 16 is limited to the first current I1 of the PMOS 13. The period in which the current I16 in accordance with the current supply capacity of the NMOS 16 flows is the short period of the transient state where the electric potential of the output signal Vo decreases from the high level to the low level; and the decrease in power efficiency due to the current I16 flowing is small.

In the level shifter 1, an output signal Vo that has level-shifted to a decrease by making a quick response to an increase in the electric potential of the input signal Vi can be produced without reducing the power efficiency in the steady state (FIGS. 2A and 2B).

The electric potential of the input signal Vi decreases from VREG_L to 0 V at time equals 41.00 μs (FIG. 3A). When the electric potential of the input signal Vi decreases to L, the NMOS 16 turns OFF. The first current I1 is cut off.

The electric potential of the first output line 7, that is, the electric potential of the output signal Vo produced at the output terminal 8 becomes the high level higher than the low level (FIG. 3B). The high level is almost equal to the electric potential V1h equals VDD of the first high potential terminal 5. The propagation delay time in the direction in which the electric potential of the output signal Vo changes from the low level to the high level is approximately 41 ns.

With respect to the decrease in the electric potential of the input signal Vi, a level shift is made at a speed determined by the first current I1 of the PMOS 13 (FIGS. 3A and 3B).

The characteristics of the current I16 of the NMOS 16 and the output signal Vo with respect to the input signal Vi of the level shifter 1 are summarized as follows.

The characteristics of the level shifter 1:

When Vi=L, I16=0, and Vo equals the high level;

In the period of the transient state where Vi changes from Vi=L to H, I16 has the current value of Formula (2), and Vo changes from the high level to the low level; and

In the period of the steady state where Vi=H, I16 has the current value of Formula (1), and Vo is the low level.

Thus, the level shifter 1 can level-shift the input signal Vi with a logic amplitude of V2h−V2l=VREG_L to the output signal Vo with a logic amplitude of V1h−V1l=VDD−VREG_H. Furthermore, in the level shifter 1, the response in the direction in which the electric potential of the output signal Vo decreases can be speeded up without reducing the power efficiency in the steady state.

Although the output signal Vo is in antiphase where the input signal Vi is inverted in the level shifter 1, the output signal Vo may be in phase where the INV 17 or the INV 18 is omitted.

The effects of the level shifter 1 will become clear by comparing to the case where the same constant current as in the steady state is passed in the transient state where the input signal Vi changes.

### FIRST COMPARATIVE EXAMPLE

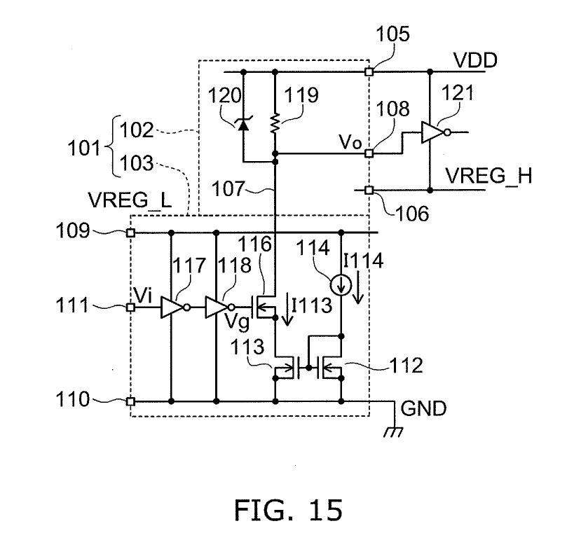

FIG. 15 is a circuit diagram of a level shifter of a first comparative example.

As shown in FIG. 15, a level shifter 101 is composed of a high side circuit 102 and a low side circuit 103.

The low side circuit 103 is connected between a low potential terminal 109 and a ground terminal 110, and outputs a current I113 to an output line 107. The ground terminal 110 is connected to the ground GND, and an electric potential VREG_L is supplied to the low potential terminal 109. The input signal Vi is inputted to the low side circuit 103 via an input terminal 111. Here, the input signal Vi is a digital signal with a logic amplitude of VREG_L.

In the low side circuit 103, an NMOS 112 and a constant current source 114 are connected in series between the low potential terminal 109 and the ground terminal 110. The source of the NMOS 112 is connected to the ground terminal 110, and the gate and the drain are connected to the constant current source 114. The constant current source 114 is connected between the NMOS 112 and the low potential terminal 109, and generates a constant current I114. The constant current I114 flows through the NMOS 112.

An NMOS 116 and an NMOS 113 are connected in series between the ground terminal 110 and the output line 107. The source of the NMOS 113 is connected to the ground terminal 110, and the drain is connected to the source of the NMOS 116. The gate of the NMOS 113 is connected to the gate of the NMOS 112. The NMOS 113 constitutes a current mirror using the NMOS 112 as the reference side. The constant current I114 generated in the constant current source 114 is turned back at the current mirror to output the current I113.

When the size ratio of the NMOS 113 and the NMOS 112 is denoted by W113/W112, the current I113 is expressed by Formula (3).

I113=I114×(W113/W112) (3)

The current I113 is outputted to the output line 107 via the NMOS 116. The drain of the NMOS 116 is connected to the output line 107. The input signal Vi is inputted to the gate of the NMOS 116 from the input terminal 111 via INVs 117 and 118.

The INVs 117 and 118 are connected between the low potential terminal 109 and the ground terminal 110. The electric potential VREG_L is supplied to the INVs 117 and 118 as a power supply potential. The INVs 117 and 118 operate using the electric potential 0 V of the ground terminal 110 as a reference. The input signal Vi is inputted to the INV 117 from the input terminal 111.

The INVs 117 and 118 invert the input signal Vi twice to produce the gate input signal Vg of the NMOS 116. The gate input signal Vg is in phase with the input signal Vi.

In the high side circuit 102, a resistor 119 is connected between a power supply terminal 105 and an output terminal 108. A Zener diode 120 is connected in parallel to the resistor 119 between the power supply terminal 105 and the output terminal 108. The output terminal 108 is connected to the output line 107. The electric potential of the output signal Vo produced at the output terminal 108 is equal to the electric potential of the output line 107.

In the low side circuit 103, the NMOS 116 turns ON or OFF in accordance with the input signal Vi, and passes the current I113 to the output line 107 or cuts off the current I113. Thereby, the electric potential of the output line 107, that is, the electric potential of the output signal Vo produced at the output terminal 108 becomes the low level or the high level.

When the current I113 flows through the output line 107, the electric potential of the output signal Vo becomes the low level that is lower than the electric potential VDD of the power supply terminal 105 by an amount of the voltage drop of the resistor 119. When the current I113 of the output line 107 is cut off, the electric potential of the output signal Vo becomes the high level that is equal to the electric potential VDD of the power supply terminal 105.

The resistance value of the resistor 119 is set such that the voltage drop of the resistor 119 is equal to VDD−VREG_H. The low level is the electric potential VREG_H of a high potential terminal 106.

The Zener diode 120 clamps the electric potential of the low level to not less than the electric voltage VREG_H of the high potential terminal 106 so that an overvoltage exceeding the element breakdown voltage of a circuit connected to the output terminal 108 may not be applied.

The output signal Vo is outputted to an INV 121 connected to the high side circuit 102. In FIG. 15, the INV 121 is illustrated as a circuit connected to the high side circuit 102. However, it is sufficient that a digital signal with a logic amplitude of VDD−VREG_H can be inputted, and other logic circuits may be used.

Next, the operation of the level shifter 101 of the first comparative example is described with reference to waveform diagrams.

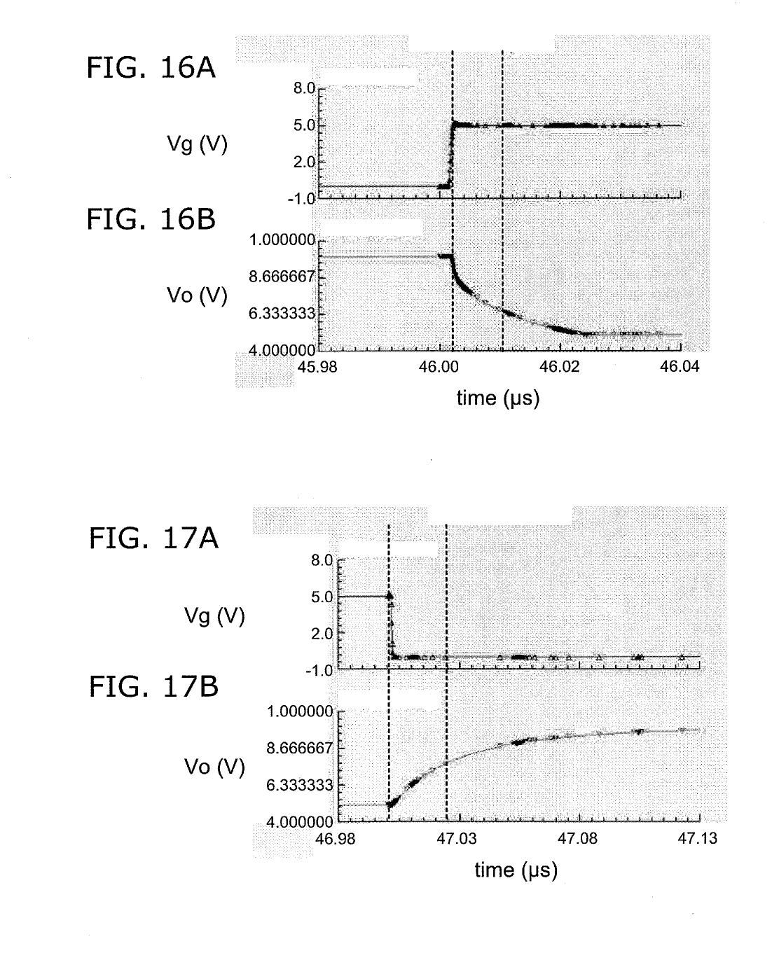

FIGS. 16A and 16B are waveform diagrams of main signals of the level shifter shown in FIG. 15, where FIG. 16A shows the gate input signal Vg, and FIG. 16B shows the output signal Vo.

FIGS. 17A and 17B are other waveform diagrams of the main signals of the level shifter shown in FIG. 15, where FIG. 17A shows the gate input signal Vg, and FIG. 17B shows the output signal Vo.

FIGS. 16A and 16B and FIGS. 17A and 17B take the time (time) on the horizontal axis and the electric potential on the vertical axis, and show the simulation results of the output signal Vo when the electric potential of the gate input signal Vg of the level shifter 101 increases and when it decreases. FIG. 16A and FIG. 17A show the electric potential of the gate input signal Vg, and FIG. 16B and FIG. 17B show the electric potential of the output signal Vo.

It is assumed that the electric potential VREG_L of the low potential terminal 109 equals 5 V, the electric potential VDD of the power supply terminal 105 equals 10 V, and the electric potential VREG_H of the high potential terminal 106 equals 5 V. Therefore, the L and the H of the electric potential of the input signal Vi are approximately 0 V and 5 V, respectively, and the low level and the high level of the output signal Vo are approximately 5 V and 10 V, respectively.

Furthermore, it is assumed that the constant current I114 of the constant current source 114 equals 10 μA, and the size ratio W113/W112 of the NMOS 113 and the NMOS 112 equals 8. From Formula (3), I113=80 μA, which is equal to the current value of the first current I1 in the simulations of FIGS. 2A and 2B and FIGS. 3A and 3B. The resistance value of the resistor 119 is 60 kΩ. The influence of the Zener diode 120 is not taken into consideration.

When the electric potential of the input signal Vi increases from L to H, the gate input signal Vg increases from L to H (FIG. 16A). When the electric potential of the input signal Vi increases and the electric potential of the gate input signal Vg becomes H, the NMOS 116 turns ON and the current I113 flows.

The electric potential of the output signal Vo produced at the output terminal 108 becomes the low level (FIG. 16B). The low level is almost equal to the electric potential VREG_H=5 V of the high potential terminal 106. The propagation delay time in the direction in which the electric potential of the output signal Vo changes from the high level to the low level is approximately 8 ns. The propagation delay time is a value that does not include the propagation delay time of the INVs 117 and 118.

As compared to the level shifter 1, in the case where the current I113 flowing through the output line 107 is a constant current, the change in the electric potential of the output signal Vo from the high level to the low level is slow. To speed up the response to the input signal Vi, it is necessary to increase the current value of the current I113.

When the electric potential of the input signal Vi decreases from H to L, the gate input signal Vg decreases from H to L (FIG. 17A). When the electric potential of the input signal Vi decreases and the electric potential of the gate input signal Vg becomes L, the NMOS 116 turns OFF. The current I113 is cut off. The electric potential of the output signal Vo produced at the output terminal 108 becomes the high level (FIG. 17B).

The propagation delay time in the direction in which the electric potential of the output signal Vo changes from the low level to the high level is approximately 23 ns. The propagation delay time is a value that does not include the propagation delay time of the INVs 117 and 118. The propagation delay time in the direction in which the electric potential of the output signal Vo increases depends on the resistance value of the resistor 119. As mentioned above, the resistance value of the resistor 119 depends on the potential difference between the electric potential VDD of the power supply terminal 105 and the electric potential VREG_H of the high potential terminal 106 and on the current value of the current I113.

Therefore, as the current value of the current I113 increases, the influence of the parasitic capacitance of the INV 121 connected to the output terminal 108 etc. is decreased, and the operating speed of the level shifter 101 is increased. However, as the current value of the current I113 increases, the power consumption is increased and the power efficiency is decreased. The current value of the current I113 poses a trade-off between the operating speed and the power efficiency. Therefore, the operating speed that can be speeded up by increasing the current value of the current I113 has a limit from the viewpoint of the power efficiency.

In the level shifter 101, the low level of the electric potential of the output signal Vo is set as the absolute value of the voltage drop of the resistor 119. Therefore, it is necessary to combine the temperature characteristics of the current value of the current I113 and the resistance value of the resistor 119. In addition, there is also a possibility that the low level will vary due to variations in the current value of the current I113 and the resistance value of the resistor 119 and will cause a voltage exceeding the element breakdown voltage of the INV 121 etc. connected to the output terminal 108.

Therefore, it is necessary to connect a clamp circuit to the output terminal 108 so that an overvoltage may not be applied. In the level shifter 101, the Zener diode 120 is connected to the output terminal 108. Although the clamp circuit is necessary in order to protect a circuit connected to the output terminal 108, the clamp circuit constitutes a factor in increasing the parasitic capacitance of the output terminal 108, and the operating speed is therefore further decreased.

### SECOND COMPARATIVE EXAMPLE

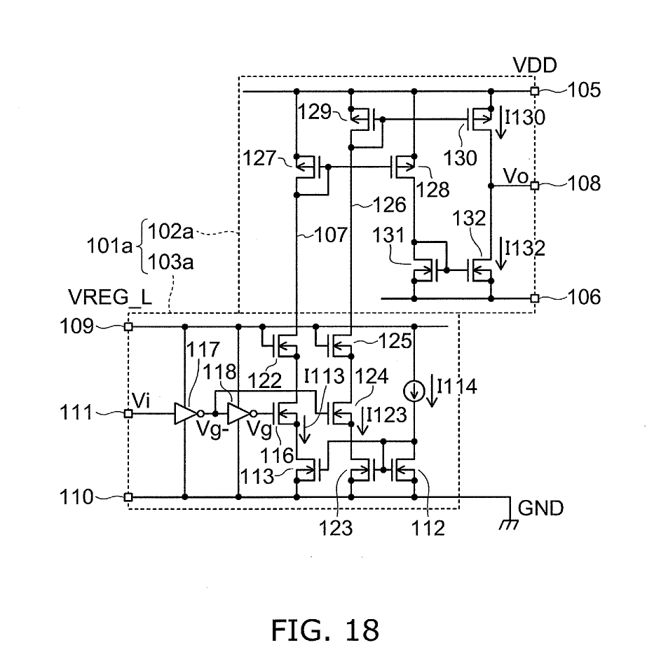

FIG. 18 is a circuit diagram of a level shifter of a second comparative example.

As shown in FIG. 18, a level shifter 101a is composed of a high side circuit 102a and a low side circuit 103a. In FIG. 18, identical components to FIG. 15 are marked with the same reference numerals.

In the low side circuit 103a, NMOSs 122 to 125 are added to the low side circuit 103 shown in FIG. 15. The NMOS 122 is connected between the NMOS 116 and the output line 107, and protects the NMOS 116 from overvoltage. The NMOS 123 constitutes a current mirror along with the NMOS 112, and outputs a current I123 to an output line 126 via the NMOS 124 and the NMOS 125. The NMOS 124 is made ON or OFF by a gate input signal Vg− obtained by inverting the input signal Vi. The NMOS 125 is connected between the NMOS 124 and the output line 126, and protects the NMOS 124 from overvoltage.

In the low side circuit 103a, the gate input signals Vg and Vg− are inputted to the NMOSs 116 and 124, respectively, as differential signals. The NMOS 116 and the NMOS 124 turn ON exclusively in accordance with the input signal Vi. The currents I113 and I123 are outputted to the output lines 107 and 126 as differential currents.

The current I113 of the output line 107 is turned back at a current mirror composed of PMOSs 127 and 128 of the high side circuit 102a, and further turned back at a current mirror composed of PMOSs 131 and 132. The PMOS 132 is connected between the output terminal 108 and the high potential terminal 106, and outputs a current I132 obtained by turning back the current I113. The current I123 of the output line 126 is turned back at a current mirror of PMOSs 129 and 130. The PMOS 130 is connected between the power supply terminal 105 and the output terminal 108, and outputs a current I130 obtained by turning back the current I123.

The size ratio of the NMOS 123 and the NMOS 112 is denoted by W123/W112, the size ratio of the PMOS 128 and the PMOS 127 is denoted by W128/W127, the size ratio of the NMOS 132 and the NMOS 131 is denoted by W132/W131, and the size ratio of the PMOS 130 and the PMOS 129 is denoted by W130/W129. The current I130 of the PMOS 130 and the current I132 of the PMOS 132 are expressed by Formulae (4) and (5), respectively.

I130=I114×(W123/W112)×(W130/W129) (4)

I132=I113×(W128/W127)×(W132/W131) (5)

Here, the current I113 is expressed by Formula (3).

The electric potential of the output signal Vo produced at the output terminal 108 is the high level when the current value of the current I130 is larger than the current value of the current I132 and the low level when smaller. The high side circuit 102a forms a current comparison circuit that compares the current values of the currents I113 and I123 of the output lines 107 and 126 and outputs the high level or the low level.

In the low side circuit 103a, the NMOS 116 and the NMOS 124 turn ON exclusively in accordance with the input signal Vi. The currents I113 and I123 flow through the output lines 107 and 126, respectively, as differential currents. Thereby, the electric potential of the output signal Vo produced at the output terminal 108 becomes the low level or the high level.

The high level is almost equal to the electric potential VDD of the power supply terminal 105, and the low level is almost equal to the electric potential VREG_H of the high potential terminal 106. Therefore, it is not necessary to provide a clamp circuit for protecting a circuit connected to the output terminal 108 like that of the level shifter 101 of the first comparative example of FIG. 15.

Next, the operation of the level shifter 101a of the second comparative example is described with reference to waveform diagrams.

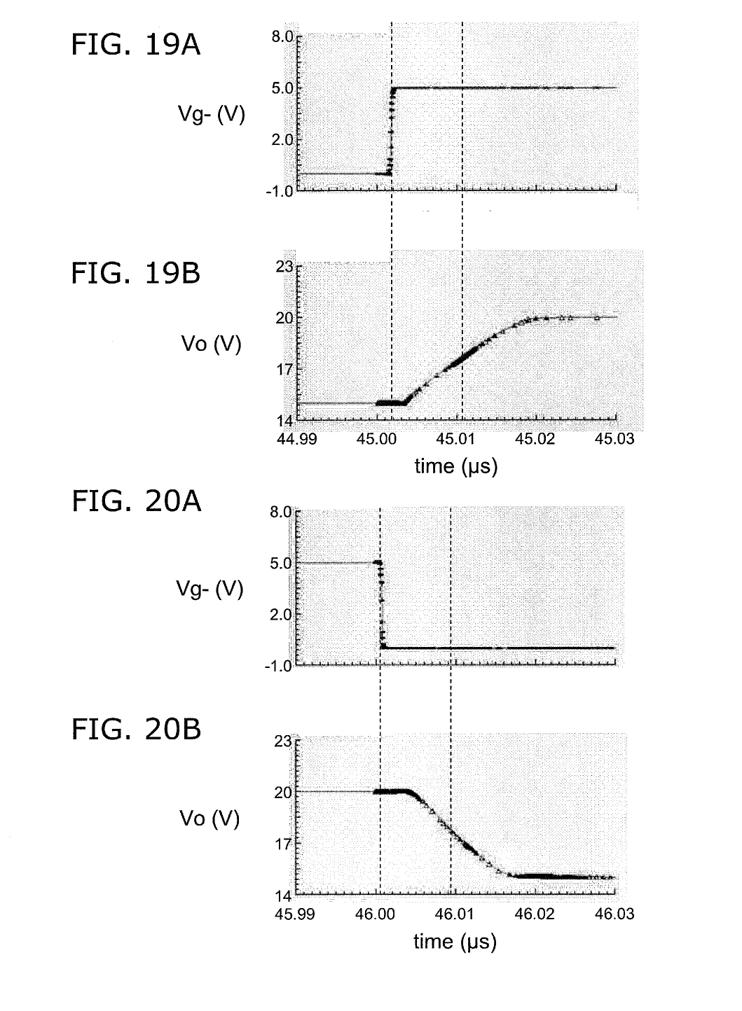

FIGS. 19A and 19B are waveform diagrams of main signals of the level shifter shown in FIG. 18, where FIG. 19A shows the gate input signal Vg−, and FIG. 19B shows the output signal Vo.

FIGS. 20A and 20B are other waveform diagrams of the main signals of the level shifter shown in FIG. 18, where FIG. 20A shows the gate input signal Vg−, and FIG. 20B shows the output signal Vo.

FIGS. 19A and 19B and FIGS. 20A and 20B take the time (time) on the horizontal axis and the electric potential on the vertical axis, and show the simulation results of the output signal Vo when the electric potential of the gate input signal Vg− of the level shifter 101a increases and when it decreases. FIG. 19A and FIG. 20A show the electric potential of the gate input signal Vg−, and FIG. 19B and FIG. 20B show the electric potential of the output signal Vo.

It is assumed that the electric potential VREG_L of the low potential terminal 109 equals 5 V, the electric potential VDD of the power supply terminal 105 equals 20 V, and the electric potential VREG_H of the high potential terminal 106 equals 15 V. Therefore, the L and the H of the electric potential of the input signal Vi are approximately 0 V and 5 V, respectively, and the low level and the high level of the output signal Vo are approximately 15 V and 20 V, respectively.

Furthermore, it is assumed that the constant current I114 of the constant current source 114 equals 10 μA, the size ratio W113/W112=W123/W112=4, W128/W127=W130/W129=2, and W132=W131. From Formulae (3) to (5), I113=I123=40 μA, and I130=I132=80 μA, which is equal to the current value of the first current I1 in the simulations of FIGS. 2A and 2B and FIGS. 3A and 3B.

When the electric potential of the input signal Vi decreases from H to L, the electric potential of the gate input signal Vg− increases from L to H (FIG. 19A). When the electric potential of the input signal Vi decreases and the electric potential of the gate input signal Vg− becomes H, the NMOS 124 turns ON and the current I123 flows. Furthermore, the NMOS 116 turns OFF, and the current I113 is cut off.

The current I130 flows, and the electric potential of the output signal Vo produced at the output terminal 108 becomes the high level (FIG. 19B). The high level is almost equal to the electric potential VDD=20 V of the power supply terminal 105.

The propagation delay time in the direction in which the electric potential of the output signal Vo changes from the low level to the high level is approximately 9 ns. The propagation delay time is a value that does not include the propagation delay time of the INV 117.

When the electric potential of the input signal Vi increases from L to H, the electric potential of the gate input signal Vg− decreases from H to L (FIG. 20A). When the electric potential of the input signal Vi increases and the electric potential of the gate input signal Vg− becomes L, the NMOS 124 turns OFF and the current I123 is cut off. Furthermore, the NMOS 116 turns ON, and the current I113 flows.

Therefore, the current I132 flows, and the electric potential of the output signal Vo produced at the output terminal 108 becomes the low level (FIG. 20B). The low level is almost equal to the electric potential VREG_H=15 V of the high potential terminal 106. The propagation delay time in the direction in which the electric potential of the output signal Vo changes from the high level to the low level is approximately 9 ns.

Since the electric potential of the output signal Vo produced at the output terminal 108 is limited within the range between the electric potential VDD of the power supply terminal 105 and the electric potential VREG_H of the high potential terminal 106, a clamp circuit like that of the level shifter 101 is not necessary. Furthermore, since the electric potential of the output signal Vo is determined by the magnitude of the current value of the currents I130 and I132, the influence of the temperature dependence, current value variation, etc. of the constant current source 114 can be reduced.

However, also in the level shifter 101a, similarly to the level shifter 101, the output terminal 108 is driven by the constant current of the current I130 or the current I132. As the current values of the currents I130 and I132 increase, the influence of the parasitic capacitance of a circuit connected to the output terminal 108 etc. is decreased, and the operating speed of the level shifter 101a is increased. However, if the current values of the currents I114, I113, and I123 are increased in order to increase the current values of the currents I130 and I132, the power consumption increases. For example, in the case of being used for a DC-DC converter, the power efficiency decreases.

Therefore, similarly to the level shifter 101, the current values of the currents I113, I123, I130, and I132 pose a trade-off between the operating speed and the power efficiency. It may be possible to optimize the operating speed and the power efficiency by appropriately setting the size ratios of the transistors forming the current mirrors. However, the operating speed that can be speeded up by increasing the current value has a limit from the viewpoint of the power efficiency.

In contrast, in the level shifter 1 shown in FIG. 1, when the electric potential of the output signal Vo changes from the high level to the low level, the output terminal 8 is driven at the current value of the current I16, which is larger than the current value of the first current I1 that is a current in a steady state. Consequently, a charge stored in a parasitic capacitance etc. is drawn from the output terminal 8, and the electric potential of the output signal Vo decreases rapidly from the high level to the low level as compared to the case where a constant current flows.

When the electric potential of the output signal Vo has become the steady state of the low level, the current value of the current that drives the output terminal 8 is limited to the first current I1 that is a current in a steady state. The period in which a current with a current value larger than the current value in the steady state flows is the short period of the transient state where the electric potential of the output signal Vo decreases from the high level to the low level; and the decrease in power efficiency due to the current I16 flowing is small.

Therefore, the level shifter 1 can level-shift the input signal Vi with a logic amplitude of V2h−V2l=VREG_L to the output signal Vo with a logic amplitude of V1h−V1l=VDD−VREG_H. Furthermore, in the level shifter 1, the response in the direction in which the electric potential of the output signal Vo decreases can be speeded up without reducing the power efficiency in the steady state.

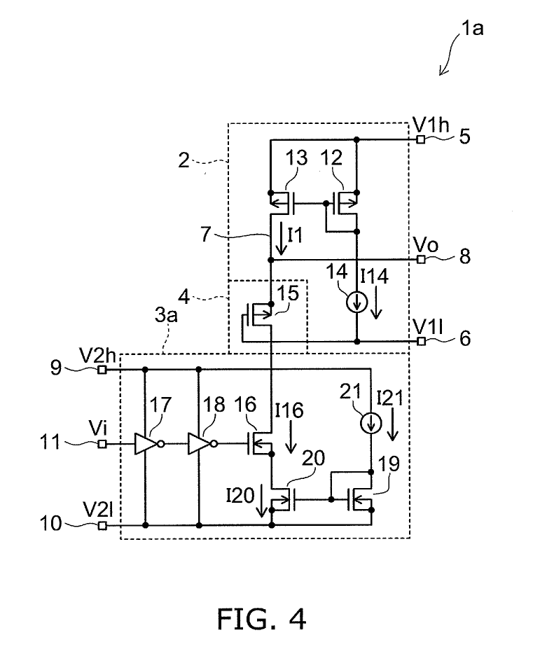

FIG. 4 is a circuit diagram illustrating another configuration of a level shifter according to the first embodiment.

In a level shifter 1a, the current switch 3 of the level shifter 1 shown in FIG. 1 is replaced with a current switch 3a. The current generator 2 and the protection circuit 4 are similar to those of the level shifter 1. In FIG. 4, identical components to FIG. 1 are marked with the same reference numerals.

In the current switch 3a, NMOSs 19 and 20 and a constant current source 21 are added to the current switch 3 shown in FIG. 1.

The NMOS 19 and the constant current source 21 are connected in series between the second high potential terminal 9 and the second low potential terminal 10. The source of the NMOS 19 is connected to the second low potential terminal 10, and the gate and the drain are connected to the constant current source 21. The constant current source 21 is connected between the NMOS 19 and the first high potential terminal 9, and generates a constant current I21. The constant current I21 flows through the NMOS 19.

The NMOS 20 is connected between the second low potential terminal 10 and the NMOS 16. The source of the NMOS 20 is connected to the second low potential terminal 10, and the drain is connected to the source of the NMOS 16. The gate of the NMOS 20 is connected to the gate of the NMOS 19. The NMOS 20 constitutes a current mirror using the NMOS 19 as the reference side. The constant current I21 generated in the constant current source 21 is turned back at the current mirror, and a current I20 flows through the NMOS 20.

When the size ratio of the NMOSs 20 and 19 is denoted by W20/W19, the current I20 is expressed by Formula (6).

I20=I21×(W20/W19) (6)

The peak value of the current I16 flowing when the NMOS 16 changes from OFF to ON is limited to the current value of the current I20 given by Formula (6). Here, by setting to I16>I20>>I1, although the response speed in the level shift decreases slightly as compared to the level shifter 1, the switching noise generated when the NMOS 16 turns ON can be reduced.

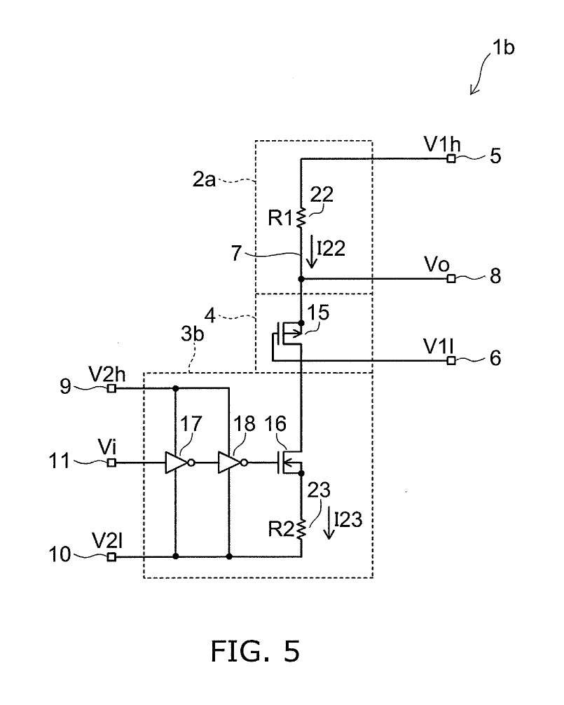

FIG. 5 is a circuit diagram illustrating another configuration of a level shifter according to the first embodiment.

In a level shifter 1b, the current generator 2 and the current switch 3 of the level shifter 1 shown in FIG. 1 are replaced with a current generator 2a and a current switch 3b, respectively. The protection circuit 4 is similar to that of the level shifter 1 shown in FIG. 1. In FIG. 5, identical components to FIG. 1 are marked with the same reference numerals.

In the current generator 2a, a resistor 22 is connected between the first high potential terminal 5 and the first output line 7.

In the current switch 3b, a resistor 23 is added to the current switch 3 shown in FIG. 1. The NMOS 16 and the INVs 17 and 18 are similar to those of the current switch 3.

When the electric potential of the input signal Vi increases and the NMOS 16 turns ON, a first current I22 flowing through the resistor 22 and a current I23 flowing through the resistor 23 are expressed by Formulae (7) and (8), respectively.

I22=(V1h−V1l−|Vgs15|)/R1 (7)

I23=(V2h−Vgs16)/R2 (8)

where Vgs15 and Vgs16 are the gate-source voltages of the PMOS 15 and the NMOS 16, respectively, and R1 and R2 are the resistance values of the resistors 22 and 23, respectively.

In the case where, for example, V1h−V1l=V2h−V2l=V2h and |Vgs15|=Vgs16, setting to R1>>R2 gives I23>>I22, and provides similar effects to the level shifter 1a shown in FIG. 4. Furthermore, setting to R2=0 provides similar effects to the level shifter 1 shown in FIG. 1.

FIG. 1 to FIG. 5 above describe the level shifters 1, 1a, and 1b in which the input signal Vi with a logic amplitude of V2h−V2l is level-shifted to output the output signal Vo with a logic amplitude of V1h−V1l. The level shifters 1, 1a, and 1b are the case of V1h>V2l, that is, they level-shift the input signal Vi of the low side block to the output signal Vo of the high side block. However, it is also possible to configure a level shifter of the case of V2h>V1l, that is, a level shifter that level-shifts the input signal Vi of the high side block to the output signal Vo of the low side block.

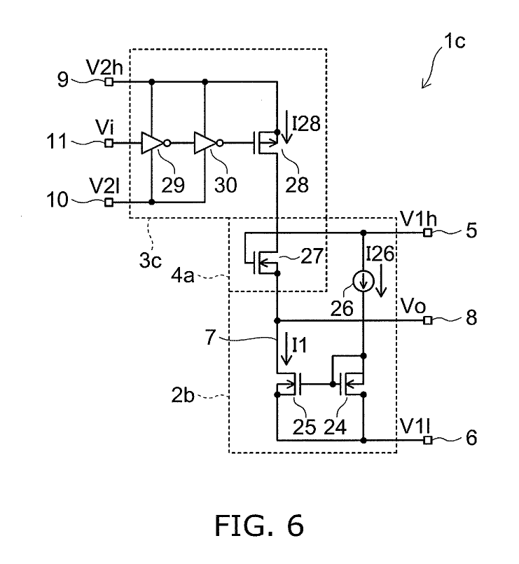

FIG. 6 is a circuit diagram illustrating another configuration of a level shifter according to the first embodiment.

As shown in FIG. 6, a level shifter 1c includes a current generator 2b, a current switch 3c, and a protection circuit 4a.

The level shifter 1c has a configuration in which the NMOS and the PMOS of the level shifter 1 shown in FIG. 1 are replaced with each other. In the level shifter 1c, the current generator 2b is configured as the low side block, and the current switch 3c is configured as the high side block. The input signal Vi of the high side block is level-shifted to the output signal Vo of the low side block.

The current generator 2b is connected between the first high potential terminal 5 and the first low potential terminal 6, and generates the first current I1 and outputs it to the first output line 7. Here, the first current I1 has a current value such that a transistor turns ON to operate. The output terminal 8 is connected to the first output line 7. The electric potential of the output signal Vo produced at the output terminal 8 is equal to the electric potential of the first output line 7.

The current switch 3c is connected between the second high potential terminal 9 and the second low potential terminal 10, and receives the first current I1. The input signal Vi is inputted to the current switch 3c via the input terminal 11. Here, the input signal Vi is a digital signal in which the electric potential changes between the electric potential V2h of the second high potential terminal 9 and the electric potential V2l of the second low potential terminal 10. Here, L and H are electric potentials at which the electric potential of the input signal Vi is the logic value 0 (false) and the logical value 1 (true), respectively.

The current switch 3c passes the first current I1 or cuts off the first current I1 in accordance with the input signal Vi. Thereby, the electric potential of the first output line 7, that is, the electric potential of the output signal Vo produced at the output terminal 8 becomes the low level or the high level higher than the low level.

The protection circuit 4a is connected to the first output line 7 between the current generator 2b and the current switch 3c. The protection circuit 4a limits the electric potential of the first output line 7 to not more than the electric potential of the first high potential terminal 5. Therefore, the high level mentioned above is limited to not more than the electric potential V1h of the first high potential terminal 5 and the low level is limited to not less than the electric potential V1l of the first low potential terminal 6. The voltage applied to the current generator 2b is limited to the potential difference V1h−V1l between the electric potential V1h of the first high potential terminal 5 and the electric potential V1l of the first low potential terminal 6. The protection circuit 4a protects the current generator 2b from overvoltage.

Thus, the current generator 2b is a low side block that operates using the electric potential V1l of the first low potential terminal 6 as a reference. Furthermore, the current switch 3c is a high side block that operates using the electric potential V2h of the second high potential terminal 9 as a reference.

The first low potential terminal 6 may be connected to, for example, the ground. The electric potential V2h of the second high potential terminal 9 is set not less than the electric potential V1h of the first high potential terminal 5. A voltage not less than the power supply voltage V1h−V1l of the low side block is supplied between the second high potential terminal 9 and the first low potential terminal 6.

The level shifter 1c level-shifts the input signal Vi with the logic amplitude V2h−V2l of the high side block, and produces the output signal Vo with the logic amplitude V1h−V1l of the low side block.

Next, the components are described in detail.

In the current generator 2b, an NMOS 24 and a constant current source 26 are connected in series between the first high potential terminal 5 and the first low potential terminal 6. The source of the NMOS 24 is connected to the first low potential terminal 6, and the gate and the drain are connected to the constant current source 26. The constant current source 26 is connected between the NMOS 24 and the first high potential terminal 5, and generates a constant current I26. The constant current I26 flows through the NMOS 24.

An NMOS 25 is connected between the first low potential terminal 6 and the first output line 7. The source of the NMOS 25 is connected to the first low potential terminal 6, and the drain is connected to the first output line 7. The gate of the NMOS 25 is connected to the gate and the drain of the NMOS 24. The NMOS 25 constitutes a current mirror using the NMOS 24 as the reference side. The constant current I26 generated in the constant current source 26 is turned back at the current mirror. The first current I1 is outputted to the first output line 7. The first current I1 is expressed similarly to Formula (1).

In the current switch 3c, a PMOS 28 is connected between the protection circuit 4a and the second high potential terminal 9. The PMOS 28 receives the first current I1 that the current generator 2b has generated via the protection circuit 4a. The drain of the PMOS 28 is connected to the first output line 7 via the protection circuit 4a. The source of the PMOS 28 is connected to the second high potential terminal 9. The input signal Vi is inputted to the gate of the PMOS 28 from the input terminal 11 via INVs 29 and 30.

The INVs 29 and 30 are connected between the second high potential terminal 9 and the second low potential terminal 10. The electric potential V2h of the second high potential terminal 9 and the electric potential V2l of the second low potential terminal 10 are supplied to the INVs 29 and 30. The INVs 29 and 30 operate using the electric potential V2h of the second high potential terminal 9 as a reference. The input signal Vi is inputted to the INV 29 from the input terminal 11.

As mentioned above, the input signal Vi is a digital signal in which the electric potential changes between the electric potential V2h of the second high potential terminal 9 and the electric potential V2l of the second low potential terminal 10. The INVs 29 and 30 invert the input signal Vi twice, and output a signal in phase with the input signal Vi. The INVs 29 and 30 are interposed in order to obtain an interface between the input signal Vi and the gate-source voltage of the PMOS 28.

The PMOS 28 turns ON or OFF in accordance with the electric potential of the input signal Vi.

When the electric potential of the input signal Vi is H that is higher than the logic threshold voltage of the INV 29, the PMOS 28 turns OFF. The first current I1 is cut off.

The current supply capacity of the PMOS 28 is expressed similarly to the I16 of Formula (2) as a current I28 that flows upon becoming ON.

The current value of the current I28 corresponding to the current supply capacity is set larger than the current value of the first current IL Therefore, the electric potential of the first output line 7, that is, the electric potential of the output signal Vo produced at the output terminal 8 becomes the low level. The low level is almost equal to the electric potential V1l of the first low potential terminal 6.

When the PMOS 28 changes from OFF to ON, the first current I1 flows through the PMOS 28, and the PMOS 28 draws a charge stored in a parasitic capacitance etc. from the output terminal 8. Consequently, the electric potential of the output signal Vo increases rapidly from the low level to the high level as compared to the case where the first current I1 of a constant current flows through the current switch 3c.

When the electric potential of the input signal Vi is L that is lower than the logic threshold voltage of the INV 29, the PMOS 28 turns ON. The first current I1 flows through the output line 7. The electric potential of the first output line 7, that is, the electric potential of the output signal Vo produced at the output terminal 8 becomes the high level higher than the low level mentioned above. As mentioned above, the high level is almost equal to the electric potential V1h of the first high potential terminal 5 due to the protection circuit 4a.

In the protection circuit 4a, an NMOS 27 is connected to the first output line 7 between the NMOS 25 of the current generator 2b and the PMOS 28 of the current switch 3c. The source of the NMOS 27 is connected to the first output line 7, and connected to the drain of the NMOS 25 via the first output line 7. The drain of the NMOS 27 is connected to the drain of the PMOS 28. The gate of the NMOS 27 is connected to the first high potential terminal 5.

When the NMOS 28 turns ON, the PMOS 27 turns ON and the first current I1 flows through the first output line 7. At this time, the electric potential of the first output line 7 is limited to an electric potential lower than the electric potential V1h of the first high potential terminal 5 by an amount of the threshold voltage Vtn of the NMOS 27.

When the NMOS 28 turns OFF, the PMOS 27 turns OFF and the first current I1 of the first output line 7 is cut off. At this time, the electric potential of the first output line 7 is drawn by the NMOS 25 that attempts to pass the first current I1, and becomes the electric potential V1l of the first low potential terminal 6.

Thus, the protection circuit 4a limits the electric potential of the first output line 7 to not more than the electric potential V1h of the first high potential terminal 5 and not less than the electric potential V1l of the first low potential terminal 6. Therefore, the voltage applied to the current generator 2b is limited within the potential difference V1h−V1l, and the current generator 2b is protected from overvoltage.

Therefore, the electric potential of the output signal Vo increases rapidly from the low level to the high level as compared to the case where the first current I1 of a constant current flows through the current switch 3c. When the electric potential of the output signal Vo has become the steady state of the high level, the current flowing through the PMOS 28 is limited to the first current I1 of the NMOS 25. The period in which the current I28 in accordance with the current supply capacity of the PMOS 28 flows is the short period of the transient state where the electric potential of the output signal Vo increases from the low level to the high level; and the decrease in power efficiency due to the current I28 flowing is small.

In the level shifter 1c, an output signal Vo that has level-shifted to an increase by making a quick response to a decrease in the electric potential of the input signal Vi can be produced without reducing the power efficiency in the steady state.

When the electric potential of the input signal Vi increases and the electric potential of a output signal of INV30 becomes higher than the threshold voltage of the PMOS 28, the PMOS 28 turns OFF. The first current I1 is cut off.

The electric potential of the first output line 7, that is, the electric potential of the output signal Vo produced at the output terminal 8 becomes the low level. The low level is almost equal to the electric potential V1l of the first low potential terminal 6.

With respect to the increase in the electric potential of the input signal Vi, a level shift is made at a speed determined by the first current I1 of the NMOS 25.

Thus, the level shifter 1c can level-shift the input signal Vi of the high side block with a logic amplitude of V2h−V2l to the output signal Vo of the low side block with a logic amplitude of V1h−V1l. Furthermore, in the level shifter 1c, the response in the direction in which the electric potential of the output signal Vo increases can be speeded up without reducing the power efficiency in the steady state.

Although the logic of the output signal Vo is in antiphase where the logic of the input signal Vi is inverted in the level shifter 1c, the logic of the output signal Vo may be in phase where the INV 29 or the INV 30 is omitted.

Furthermore, although the level shifter 1c is configured similarly to the level shifter 1 shown in FIG. 1, it may be configured similarly to the level shifter 1a or 1b.

As described above with reference to FIG. 1 to FIG. 6, in the level shifter according to the first embodiment, a current with a current value larger than the current value in the steady state flows through the current switch in the period of the transient state where the electric potential of the output signal Vo changes. When the electric potential of the output signal Vo becomes the steady state, the current flowing through the current switch becomes a current with a steady-state value. Consequently, the response in the direction in which the electric potential of the output signal Vo decreases or in the direction in which it increases is speeded up without reducing the power efficiency in the steady state. Thus, the level shifter according to the first embodiment can perform high-speed operation with low power consumption.

### Second Embodiment

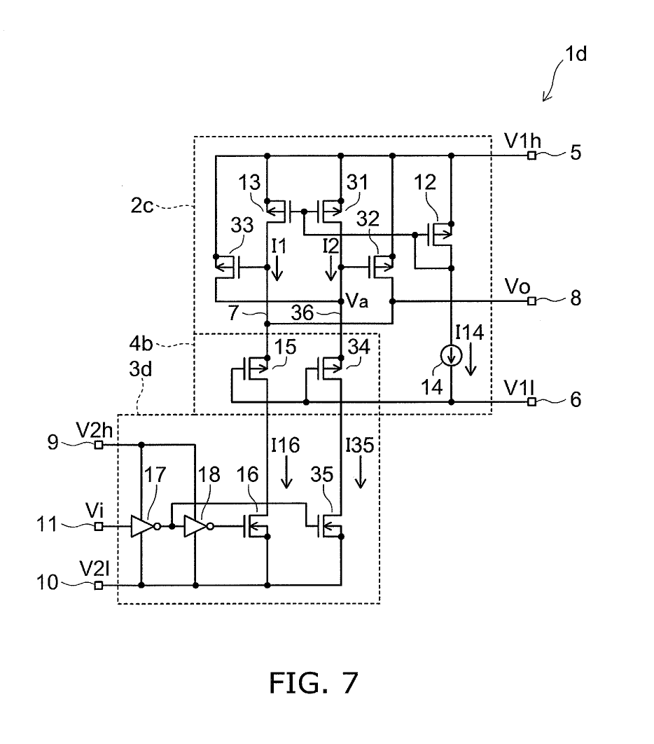

FIG. 7 is a circuit diagram illustrating a configuration of a level shifter according to a second embodiment.

As shown in FIG. 7, a level shifter 1d includes a current generator 2c, a current switch 3d, and a protection circuit 4b. In FIG. 7, identical components to FIG. 1 are marked with the same reference numerals.

In the current generator 2c, a PMOS 31, a first transistor 32, a second transistor 33, and a second output line 36 are added to the current generator 2 shown in FIG. 1.

The PMOS 31 is connected between the first high potential terminal 5 and the second output line 36. The source of the PMOS 31 is connected to the first high potential terminal 5, and the drain is connected to the second output line 36. The gate of the PMOS 31 is connected to the gate of the PMOS 13 and the gate and the drain of the PMOS 12.

The PMOS 31 constitutes a current mirror using the PMOS 12 as the reference side similarly to the PMOS 13. The constant current I14 generated in the constant current source 14 is turned back at the current mirror. A second current I2 is outputted to the second output line 36. The second current I2 is expressed similarly to Formula (1) by the size ratio of the PMOSs 31 and 12.

The first transistor 32 is connected between the first high potential terminal 5 and the first output line 7. The source of the first transistor 32 is connected to the first high potential terminal 5, and the drain is connected to the first output line 7. The gate of the first transistor 32 is connected to the second output line 36. The first transistor 32 is ON when the electric potential of the second output line 36 is the low level.

The second transistor 33 is connected between the first high potential terminal 5 and the second output line 36. The source of the second transistor 33 is connected to the first high potential terminal 5, and the drain is connected to the second output line 36. The gate of the second transistor 33 is connected to the first output line 7. The second transistor 33 is ON when the electric potential of the first output line 7 is the low level.

In the current switch 3d, an NMOS 35 is added to the current switch 3 shown in FIG. 1. The NMOS 35 is connected between the protection circuit 4b and the second low potential terminal 10. The drain of the NMOS 35 is connected to the second output line 36 via the protection circuit 4b, and the source is connected to the second low potential terminal 10. A signal V17 obtained by inverting the input signal Vi via the INV 17 is inputted to the gate of the NMOS 35.

The NMOS 35 receives the second current I2 that the current generator 2c has generated via the protection circuit 4b.

In accordance with the input signal Vi, the NMOS 16 passes the first current I1 and the NMOS 35 cuts off the second current I2; or the NMOS 16 cuts off the first current I1 and the NMOS 35 passes the second current I2. Thereby, the electric potential of the first output line 7 and the electric potential of the second output line 36 become the low level or the high level. When the electric potential of the first output line 7 is the high level, the electric potential of the second output line 36 is the low level. When the electric potential of the first output line 7 is the low level, the electric potential of the second output line 36 is the high level.

In the protection circuit 4b, a PMOS 34 is added to the protection circuit 4 shown in FIG. 1. The PMOS 34 is connected to the second output line 36 between the PMOS 31 of the current generator 2c and the NMOS 35 of the current switch 3d. The source of the PMOS 34 is connected to the drain of the PMOS 31 via the second output line 36. The drain of the PMOS 34 is connected to the drain of the NMOS 35. The gate of the PMOS 34 is connected to the first low potential terminal 6.

When the NMOS 35 turns ON, the PMOS 34 turns ON and the second current I2 flows through the second output line 36. At this time, the electric potential of the second output line 36 is limited to an electric potential higher than the electric potential V1l of the first low potential terminal 6 by an amount of the inter-source/gate voltage Vsg34 of the PMOS 34 (lower by an amount of the gate-source voltage Vgs34).

When the NMOS 35 turns OFF, the PMOS 34 turns OFF and the second current I2 of the second output line 36 is cut off. At this time, the electric potential of the second output line 36 is drawn by the PMOS 31 that attempts to pass the second current I2, and becomes the electric potential V1h of the first high potential terminal 5.

The protection circuit 4b limits the voltage applied to the current generator 2c via the second output line 36 to the potential difference V1h−V1l between the electric potential V1h of the first high potential terminal 5 and the electric potential V1l of the first low potential terminal 6, and protects the current generator 2c from overvoltage.

Thus, the level shifter 1d level-shifts the input signal Vi with a logic amplitude of V2h−V2l to produce the output signal Vo with a logic amplitude of V1h−V1l.

The current generator 2c is a high side block that operates using the electric potential V1h of the first high potential terminal 5 as a reference. The current switch 3d is a low side block that operates using the electric potential V2l of the second low potential terminal 10 as a reference.

Next, the operation of the level shifter 1d is described with reference to waveform diagrams.

FIGS. 8A to 8C are waveform diagrams of main signals of the level shifter, where FIG. 8A shows the input signal Vi, FIG. 8B shows the output signal Vo, and the FIG. 8C shows the electric potential Va of the second output line.

FIGS. 9A to 9C are other waveform diagrams of the main signals of the level shifter, where FIG. 9A shows the input signal Vi, FIG. 9B shows the output signal Vo, and FIG. 9C shows the electric potential Va of the second output line.

FIGS. 8A to 8C and FIGS. 9A to 9C take the time (time) on the horizontal axis and the electric potential on the vertical axis, and show the simulation results of the output signal Vo and the electric potential Va of the second output line 36 when the electric potential of the input signal Vi of the level shifter 1d increases and when it decreases.

It is assumed that the electric potential V2h of the second high potential terminal 9 equals VREG_L, the electric potential V2l of the second low potential terminal 10 equals 0 V, the electric potential V1h of the first high potential terminal 5 equals VDD, and the electric potential V1l of the first low potential terminal 6 equals VREG_H. Furthermore, it is assumed that the constant current I14 of the constant current source 14 equals 10 μA, the size ratio W13/W12 of the PMOS 13 and the PMOS 12 equals 8, and the size ratio W31/W12 of the PMOS 31 and the PMOS 12 equals 8. Both of the first current I1 and the second current I2 are 80 μA.

The electric potential of the input signal Vi increases from 0 V to VREG_L at time=38.00 has (FIG. 8A). When the electric potential of the input signal Vi increases to higher than the threshold voltage of the NMOS 16, the NMOS 16 turns ON and the NMOS 35 turns OFF. The first current I1 flows, and the second current I2 is cut off.

The electric potential of the output signal Vo produced at the output terminal 8 becomes the low level (FIG. 8B). The low level is almost equal to the electric potential V1l=VREG_H of the first low potential terminal 6 due to the protection circuit 4b. The propagation delay time in the direction in which the electric potential of the output signal Vo changes from the high level to the low level is approximately 0.7 ns. The value of the propagation delay time is almost equal to the propagation delay time of the level shifter 1 shown in FIG. 2B.

While the electric potential Va of the second output line 36 is the low level, the first transistor 32 is ON (FIG. 8C). Therefore, when the electric potential of the input signal Vi increases from 0 V to VREG_L, the electric potential V1h=VDD is supplied from the first high potential terminal 5 to the first output line 7 via the first transistor 32.

Therefore, when the relationships of Formula (9) hold among the first current I1, the current I16 of the NMOS 16, and the current I32 of the first transistor 32, the electric potential of the output signal Vo decreases from the high level to the low level.

I16>I1+I32>I32 (9)

The current I32 of the first transistor 32 is expressed by Formula (10).

I32=(βp/2)×(Vgs32−Vtp)² (10)

where βp is a constant determined by the structure, such as the configuration, of the PMOS 32, Vgs32 is the gate-source voltage, and Vtp is the threshold voltage.

Substituting Formulae (2) and (10) into Formula (9) gives Formula (11).

(βp/βn)<((Vgs16−Vtn)/(Vgs32−Vtp))² (11)

The gate-source voltage Vgs16 of the NMOS 16 and the gate-source voltage Vgs32 of the PMOS 32 are expressed by Formulae (12) and (13), respectively.

$$\begin{matrix}Vgs 16 = V 2 h - V 2 l = VREG\_L & ( 12 ) \\ \begin{matrix}Vgs 32 = V 1 h - V 1 l - \vert Vgs 34 \vert \\ = VDD - VREG\_H - \vert Vgs 34 \vert\end{matrix} & ( 13 )\end{matrix}$$

For example, assuming that VREG_L=VREG_H=5 V, VDD=10 V, |Vgs34|=1.5 V, and Vtn=|Vtp|=1 V, βp/βn<2.56 is given from Formulae (11) to (13). With a design margin, setting is made to βp/βn<<2.56.

In the level shifter 1d, the first output line 7 and the second output line 36 are formed of symmetrical differential circuits. Similar relationships hold also for the second current I2 of the PMOS 31, the current I33 of the second transistor 33, and the current I35 of the PMOS 34 and the NMOS 35.

Therefore, when the NMOS 16 changes from OFF to ON, the first current I1 and the current I32 of the first transistor 32 flow through the NMOS 16, and a charge stored in a parasitic capacitance etc. is drawn into the NMOS 16 from the output terminal 8.

The electric potential of the output signal Vo decreases rapidly from the high level to the low level.

When the electric potential of the first output line 7, that is, the electric potential of the output signal Vo changes from the high level to the low level, the second transistor 33 turns ON. The electric potential V1h=VDD is supplied from the first high potential terminal 5 to the second output line 36 via the first transistor 33.

Therefore, when the relationships of Formula (14) hold among the second current I2, the current I35 of the NMOS 35, and the current I33 of the second transistor 33, the electric potential Va of the second output line 36 increases from the low level to the high level.

I35<I33<I2+133 (14)

Here, I2<<I33.

The electric potential Va of the second output line 36 increases rapidly from the low level to the high level as compared to the propagation delay time of the level shifter 1 of FIGS. 3A and 3B (FIG. 8C). The electric potential of the high level is almost equal to the electric potential V1h=VDD of the first high potential terminal 5.

The electric potential of the output signal Vo decreases rapidly from the high level to the low level as compared to the case where the first current I11 of a constant current flows through the current switch 3d. When the electric potential of the output signal Vo becomes the low level and the electric potential Va of the second output line 36 becomes the steady state of the high level, the first transistor 32 becomes OFF.

The current flowing through the NMOS 16 is limited to the first current I1 of the PMOS 13. The period in which the current I16 in accordance with the current supply capacity of the NMOS 16 flows is the short period of the transient state where the electric potential of the output signal Vo decreases from the high level to the low level. The decrease in power efficiency due to the current I16 flowing is small.

The period in which the current I33 flows from the high potential terminal 5 to the second output line 36 via the second transistor 33 is the short period of the transient state where the electric potential Va of the second output line 36 increases from the low level to the high level. Therefore, the decrease in power efficiency due to the current I33 is small.

In the level shifter 1d, an output signal Vo that has level-shifted to a decrease by making a quick response to an increase in the electric potential of the input signal Vi can be produced without reducing the power efficiency in the steady state (FIGS. 8A and 8B).

The electric potential of the input signal Vi decreases from VREG_L to 0 V at time=39.00 μs (FIG. 9A). When the electric potential of the input signal Vi decreases to lower than the threshold voltage of the NMOS 16, the NMOS 16 turns OFF and the NMOS 35 turns ON. The first current I1 is cut off, and the second current I2 flows.

In the level shifter 1d, the NMOS 16 and the NMOS 35 turn ON exclusively in accordance with the input signal Vi, and are configured symmetrically with respect to the first output line 7 and the second output line 36. Therefore, with respect to the decrease in the electric potential of the input signal Vi, the operation is similar to the operation in the case where the electric potential of the input signal Vi mentioned above increases. This is the operation in which the relationship between the first output line 7 and the second output line 36 is reversed.

The electric potential Va of the second output line 36 becomes the low level (FIG. 9C). The low level is almost equal to the electric potential V1l=VREG_H of the first low potential terminal 6 due to the protection circuit 4b.

The propagation delay time in the direction in which the electric potential Va of the second output line 36 changes from the high level to the low level is approximately 0.5 ns.

When the electric potential Va of the second output line 36 changes from the high level to the low level, the electric potential of the first output line 7, that is, the electric potential of the output signal Vo increases from the low level to the high level (FIG. 9B). The propagation delay time in the direction in which the electric potential of the output signal Vo changes from the low level to the high level is approximately 1.5 ns.

The electric potential of the high level is almost equal to the electric potential V1h=VDD of the first high potential terminal 5.

In the level shifter 1d, an output signal Vo that has level-shifted to an increase by making a quick response to a decrease in the electric potential of the input signal Vi can be produced without reducing the power efficiency in the steady state (FIGS. 9A and 9B).

Thus, in the level shifter 1d, an output signal Vo that has level-shifted by making a quick response to a change in the electric potential of the input signal Vi can be produced without reducing the power efficiency in the steady state.

However, since it is necessary to satisfy the relationship of Formula (11), the propagation delay time in the direction in which the electric potential of the output signal Vo increases from the low level to the high level is long as compared to the propagation delay time in the direction in which it decreases from the high level to the low level.

As described above with reference to FIG. 7A to FIG. 9C, in the level shifter according to the second embodiment, a current with a current value larger than the current value in the steady state flows through the current switch in the period of the transient state where the electric potential of the output signal Vo changes. When the electric potential of the output signal Vo becomes the steady state, the current flowing through the current switch becomes a current with a steady-state value. In the period of the transient state where the electric potential of the output signal Vo changes, the first and second transistors of the current generator turn ON, and supply the electric potential of the first high potential terminal or the first low potential terminal to the output terminal.

Consequently, an output signal Vo that has level-shifted by making a quick response to a change of the input signal Vi can be produced without reducing the power efficiency in the steady state. Thus, the level shifter according to the second embodiment can operate at higher speed with low power consumption.

### Third Embodiment

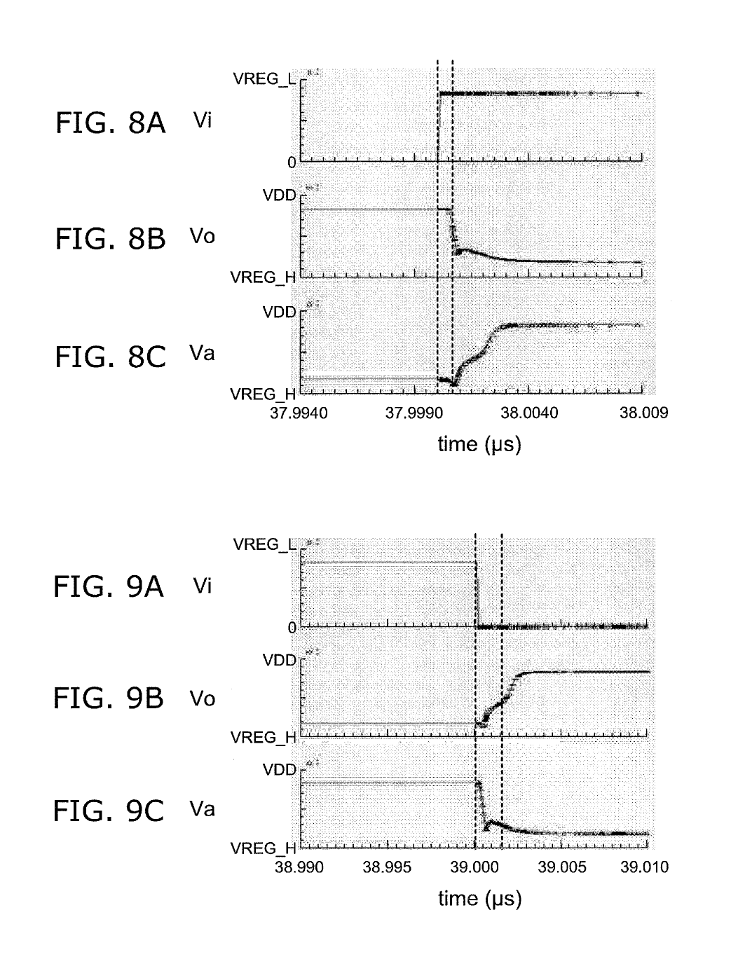

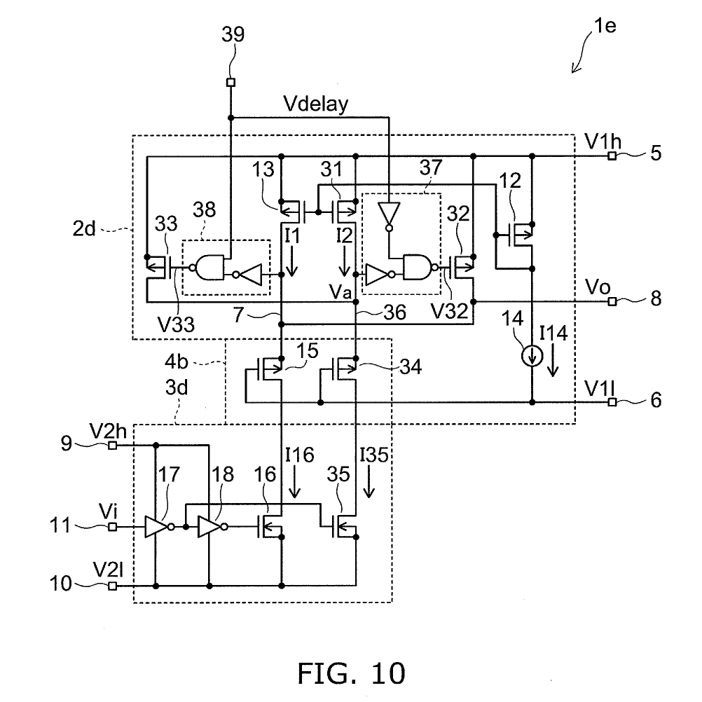

FIG. 10 is a circuit diagram illustrating a configuration of a level shifter according to a third embodiment.

In a level shifter 1e, the current generator 2c of the level shifter 1d shown in FIG. 7 is replaced with a current generator 2d. The current switch 3d and the protection circuit 4b are similar to those of the level shifter 1d. In FIG. 10, identical components to FIG. 7 are marked with the same reference numerals.

In the current generator 2d, gate signal generators 37 and 38 are added to the current generator 2c shown in FIG. 7.

The gate signal generator 37 produces a gate signal V32 that is turned to the low level for a specified period from when the electric potential Va of the second output line 36 has changed from the high level to the low level. The gate signal generator 37 produces the logical sum of the electric potential Va of the second output line 36 and a signal Vdelay obtained by delaying the output signal Vo by an amount of the specified period.

The specified period is set longer than the period from when the input signal Vi has changed till when the electric potential of the first output line 7 changes from the low level to the high level and the period from when the input signal Vi has changed till when the electric potential Va of the second output line 36 changes from the low level to the high level. The specified period is set so as to make it possible to mask the period in which the electric potential of the first output line 7 holds the low level from when the input signal Vi has changed and the period in which the electric potential Va of the second output line 36 holds the low level from when the input signal Vi has changed.

The gate signal V32 is inputted to the gate of the first transistor 32. The first transistor 32 is OFF when the electric potential Va of the second output line 36 is the high level; is turned to ON for the specified period from when the electric potential Va has changed from the high level to the low level; and turns OFF after the specified period has elapsed.

The gate signal generator 38 produces a gate signal V33 that is turned to the low level for the specified period from when the electric potential of the first output line 7, that is, the electric potential of the output signal Vo has changed from the high level to the low level. In FIG. 10, the gate signal generator 38 produces the logical sum of the electric potential Va of the second output line 36 and the signal Vdelay. Although the gate signal generators 37 and 38 are composed of a negative AND circuit (NAND) and an INV(s) in FIG. 10, other configurations are possible to the extent that the gate signals V32 and V33 mentioned above can be produced.

The gate signal V33 is inputted to the gate of the second transistor 33. The second transistor 33 is OFF when the electric potential of the output signal Vo is the high level; is turned to ON for the specified period from when the electric potential of the output signal Vo has changed from the high level to the low level; and turns OFF after the specified period has elapsed.

Next, the operation of the level shifter 1e is described with reference to waveform diagrams.

FIGS. 11A to 11F are waveform diagrams of main signals of the level shifter, where FIG. 11A shows the input signal Vi, FIG. 11B shows the output signal Vo, FIG. 11C shows the electric potential Va of the second output line, FIG. 11D shows the delay signal Vdelay, and FIG. 11E and FIG. 11F show the gate signals V32 and V33 of the first and second transistors, respectively.

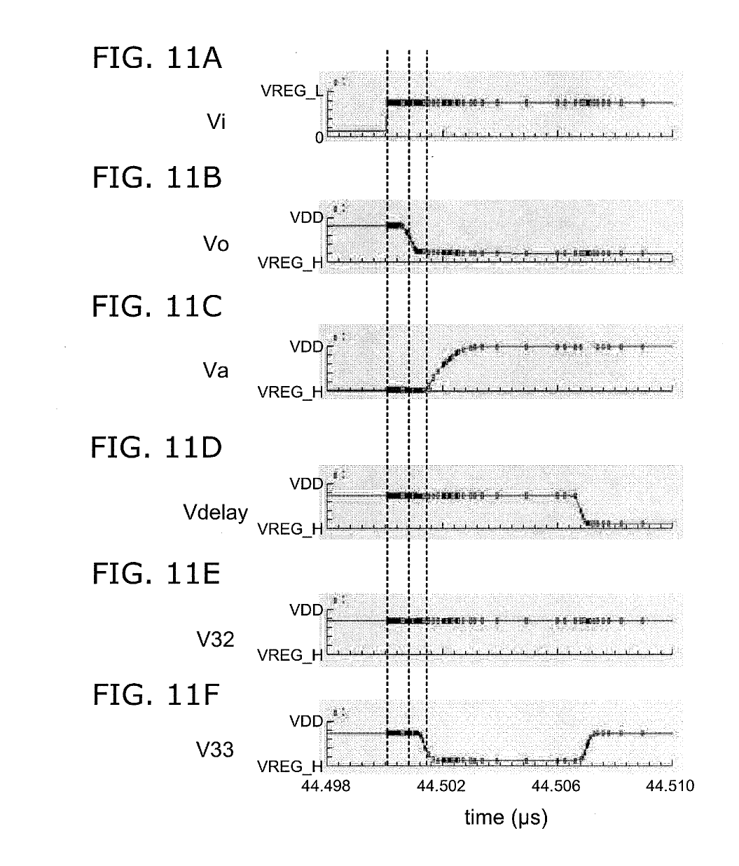

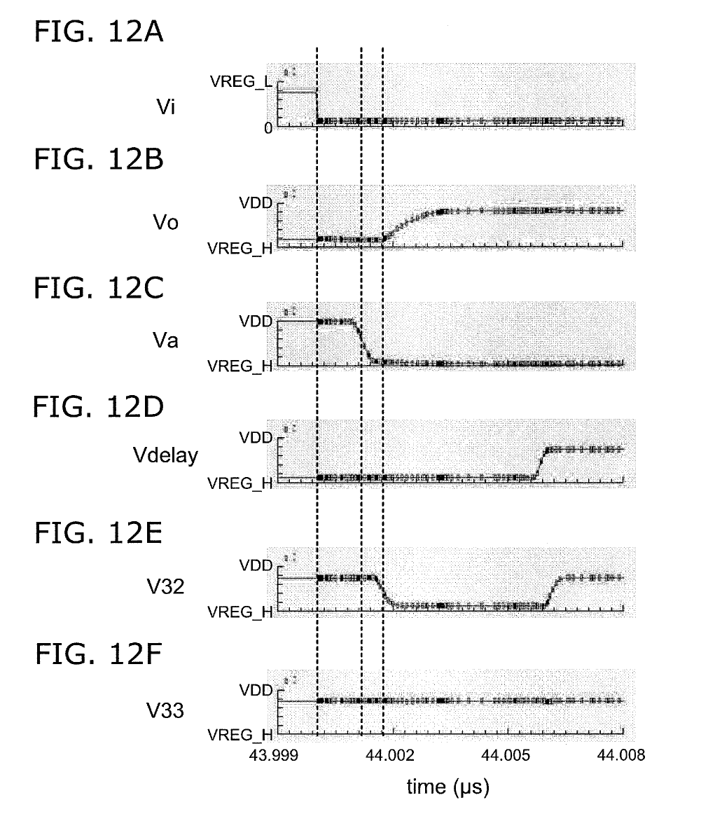

FIGS. 12A to 12F are other waveform diagrams of main signals of the level shifter, where FIG. 12A shows the input signal Vi, FIG. 12B shows the output signal Vo, FIG. 12C shows the electric potential Va of the second output line, FIG. 12D shows the delay signal Vdelay, and FIG. 12E and FIG. 12F show the gate signals V32 and V33 of the first and second transistors, respectively.

FIGS. 11A to 11F and FIGS. 12A to 12F take the time (time) on the horizontal axis and the electric potential on the vertical axis, and show the simulation results of the output signal Vo, the electric potential Va of the second output line 36, the delay signal Vdelay, and the gate signals V32 and V33 of the first and second transistors when the electric potential of the input signal Vi of the level shifter 1e increases and when it decreases.

Similarly to FIGS. 8A to 8C and FIGS. 9A to 9C, it is assumed that the electric potential V2h of the second high potential terminal 9 equals VREG_L, the electric potential V2l of the second low potential terminal 10 equals 0 V, the electric potential V1h of the first high potential terminal 5 equals VDD, and the electric potential V1l of the first low potential terminal 6 equals VREG_H. Furthermore, it is assumed that the constant current I14 of the constant current source 14 equals 10 μA, the size ratio W13/W12 of the PMOS 13 and the PMOS 12 equals 8, and the size ratio W31/W12 of the PMOS 31 and the PMOS 12 equals 8. Both of the first current I1 and the second current I2 are 80 μA. The delay signal Vdelay is a signal obtained by delaying the output signal Vo using an even number of INVs.

The electric potential of the input signal Vi increases from 0 V to VREG_L at time=44.500 has (FIG. 11A). When the electric potential of the input signal Vi increases to higher than the threshold voltage of the NMOS 16, the NMOS 16 turns ON and the NMOS 35 turns OFF. The first current I1 flows, and the second current I2 is cut off.

The electric potential of the output signal Vo produced at the output terminal 8 becomes the low level (FIG. 11B). The low level is almost equal to the electric potential V1l=VREG_H of the first low potential terminal 6 due to the protection circuit 4b. The propagation delay time in the direction in which the electric potential of the output signal Vo changes from the high level to the low level is approximately 0.7 ns. The value of the propagation delay time is a value equal to the propagation delay time of the level shifter 1 shown in FIG. 2B and the propagation delay time of the level shifter 1d shown in FIG. 8B.

Although the electric potential Va of the second output line 36 is the low level (FIG. 11C), since the delay signal Vdelay is the high level (FIG. 11D), the gate signal generator 37 outputs the high level as the gate signal V32 (FIG. 11E). The first transistor 32 is OFF. Therefore, when the electric potential of the input signal Vi increases from 0 V to VREG_L, the influence of the first transistor 32 like that in the level shifter 1d shown in FIGS. 8A to 8C does not exist, and the constraint of Formula (11) does not exist. Consequently, when the NMOS 16 changes from OFF to ON, the first current I1 flows through the NMOS 16, and a charge stored in a parasitic capacitance etc. is drawn into the NMOS 16 from the output terminal 8.

Therefore, similarly to the level shifter 1 shown in FIG. 1, the electric potential of the output signal Vo decreases rapidly from the high level to the low level. When the electric potential of the output signal Vo has become the steady state of the low level, the current flowing through the NMOS 16 is limited to the first current I1 of the PMOS 13. The period in which the current I16 in accordance with the current supply capacity of the NMOS 16 flows is the short period of the transient state where the electric potential of the output signal Vo decreases from the high level to the low level; and the decrease in power efficiency due to the current I16 flowing is small.

When the electric potential of the first output line 7, that is, the electric potential of the output signal Vo has changed from the high level to the low level, the gate signal generator 38 outputs the low level as the gate signal V33 for the specified period (FIG. 11F). The second transistor 33 is turned to ON for the specified period from when the electric potential of the output signal Vo (the electric potential of the first output line 7) has become the low level.

The electric potential V1h=VDD is supplied from the first high potential terminal 5 to the second output line 36 via the second transistor 33.

As mentioned above, in the level shifter 1e, since the constraint of Formula (11) does not exist, the current supply capacity of the second transistor 33 can be set large similarly to the NMOS 16. Therefore, the electric potential Va of the second output line 36 increases rapidly from the low level to the high level as compared to the propagation delay time of FIG. 7 (FIG. 11C). The electric potential of the high level is almost equal to the electric potential V1h=VDD of the first high potential terminal 5.

The electric potential of the output signal Vo decreases rapidly from the high level to the low level as compared to the case where the first current I1 of a constant current flows through the current switch 3d. When the electric potential of the output signal Vo becomes the steady state after the lapse of the specified period from when it has become the low level, the second transistor 33 turns OFF.

The current flowing through the NMOS 16 is limited to the first current I1 of the PMOS 13. The period in which the current I16 in accordance with the current supply capacity of the NMOS 16 flows is the short period of the transient state where the electric potential of the output signal Vo decreases from the high level to the low level. The decrease in power efficiency due to the current I16 flowing is small.

The period in which the current I33 flows from the first high potential terminal 5 to the second output line 36 via the second transistor 33 is the short period of the specified period mentioned above. Therefore, the decrease in power efficiency due to the current I33 is small.

In the level shifter 1e, an output signal Vo that has level-shifted to a decrease by making a quick response to an increase in the electric potential of the input signal Vi can be produced without reducing the power efficiency in the steady state (FIGS. 11A and 11B).

The electric potential of the input signal Vi decreases from VREG_L to 0 V at time=44.000 μs (FIG. 12A). When the electric potential of the input signal Vi decreases to lower than the threshold voltage of the NMOS 16, the NMOS 16 turns OFF and the NMOS 35 turns ON. The first current I1 is cut off, and the second current I2 flows.

In the level shifter 1e, in accordance with the input signal Vi, the NMOS 16 and the NMOS 35 turn ON exclusively, and are configured symmetrically with respect to the first output line 7 and the second output line 36. Therefore, with respect to the decrease in the electric potential of the input signal Vi, the operation is similar to the operation in the case where the electric potential of the input signal Vi mentioned above increases. This is the operation in which the relationship between the first output line 7 and the second output line 36 is reversed.

The electric potential Va of the second output line 36 becomes the low level (FIG. 12C). The low level is almost equal to the electric potential V1l=VREG_H of the first low potential terminal 6 due to the protection circuit 4b.

The propagation delay time in the direction in which the electric potential Va of the second output line 36 changes from the high level to the low level is approximately 1.1 ns.

When the electric potential Va of the second output line 36 changes from the high level to the low level, the electric potential of the first output line 7, that is, the electric potential of the output signal Vo increases from the low level to the high level (FIG. 12B). The propagation delay time in the direction in which the electric potential of the output signal Vo changes from the low level to the high level is approximately 2.3 ns.

Thus, in the level shifter 1e, an output signal Vo that has level-shifted by making a quick response to a change in the electric potential of the input signal Vi can be produced without reducing the power efficiency in the steady state.

Furthermore, since it is not necessary to satisfy the relationship of Formula (11), the propagation delay time in the direction in which the electric potential of the output signal Vo increases from the low level to the high level can be reduced as compared to the level shifter 1d.

As described above with reference to FIG. 10 to FIG. 12F, in the level shifter according to the third embodiment, a current with a current value larger than the current value in the steady state flows through the current switch in the period of the transient state where the electric potential of the output signal Vo changes. When the electric potential of the output signal Vo becomes the steady state, the current flowing through the current switch becomes a current with a steady-state value. Through the specified period in which the electric potential of the output signal Vo changes, the first and second transistors of the current generator are turned to ON, and supply the electric potential of the first high potential terminal or the first low potential terminal to the output terminal.

Consequently, an output signal Vo that has level-shifted by making a quicker response to a change of the input signal Vi can be produced without reducing the power efficiency in the steady state. Thus, the level shifter according to the third embodiment can operate at a higher speed with low power consumption.

### Fourth Embodiment

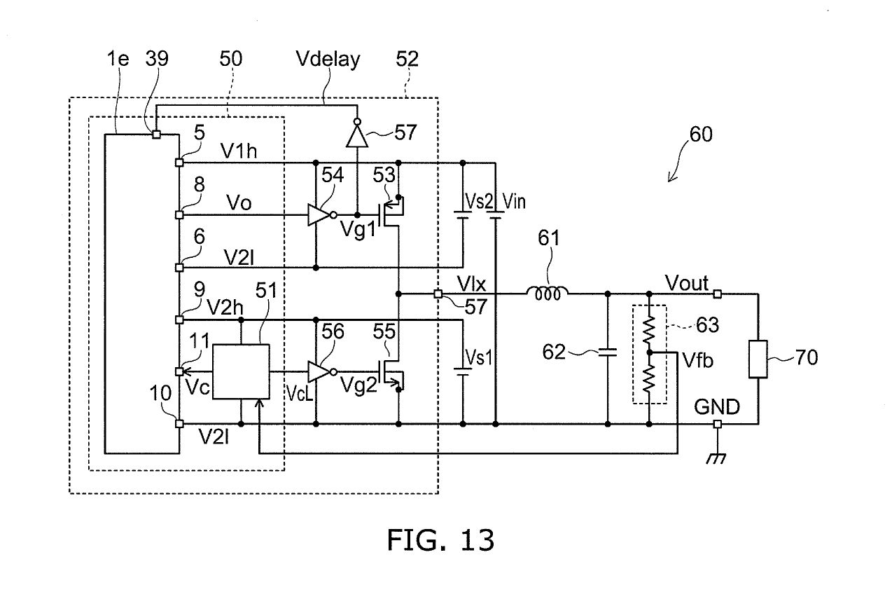

FIG. 13 is a circuit diagram illustrating a configuration of a DC-DC converter including a controller according to a fourth embodiment.

As shown in FIG. 13, in a controller 50, a PWM circuit 51 is connected between the second high potential terminal 9 and the second low potential terminal 10 of the level shifter 1e. The PWM circuit 51 produces a control signal Vc of PWM, and outputs it to the input terminal 11 of the level shifter 1e.

A second power supply voltage Vs2 is supplied between the second high potential terminal 9 and the second low potential terminal 10. The PWM circuit 51 operates with the second power supply voltage Vs2. The second low potential terminal 10 is connected to the ground Gnd, and the electric potential V2l of the second low potential terminal 10 is 0 V. The electric potential V2h of the second high potential terminal 9 is equal to the second power supply voltage Vs2.

A first power supply voltage Vs1 is supplied between the first high potential terminal 5 and the first low potential terminal 6.

The controller 50 quickly level-shifts the control signal Vc in which the logic amplitude is the second power supply voltage Vs2 to a signal in which the logic amplitude is the first power supply voltage Vs1, and outputs the resulting signal to the output terminal 8 as the output signal Vo.

In a controller 52, a first switch element 53 that is controlled by the output signal Vo of the controller 50 and a second switch element 55 that is controlled by the controller 50 are added to the controller 50. The first switch element 53 is a high side switch, and the second switch element 55 is a low side switch.

The first switch element 53 is connected between the first high potential terminal 5 and a drive terminal 57. The gate (control terminal) of the first switch element 53 is connected to the output terminal 8 of the controller 50 via a drive circuit 54. The first switch element 53 is PWM-controlled by the output signal Vo of the controller 50 via the drive circuit 54. The first switch element 53 is formed of a PMOS, and the drive circuit 54 is formed of an INV.

The second switch element 55 is connected in series to the first switch element 53 between the drive terminal 57 and the second low potential terminal 10. The second switch element 55 is PWM-controlled by a control signal VcL of PWM produced in the controller 50 via a drive circuit 56. The second switch element 55 is formed of an NMOS, and the drive circuit 56 is formed of an INV.

A third power supply voltage Vin is supplied between the first high potential terminal 5 and the second low potential terminal 10.

The control signal Vc produced in the PWM circuit 51 is level-shifted by the level shifter 1e, and is supplied to the gate of the first switch element 53 via the drive circuit 54. The gate potential Vg1 of the first switch element 53 changes into the high level or the low level in accordance with the control signal Vc. The first switch element 53 is controlled to ON or OFF in accordance with the control signal Vc.

The gate potential Vg2 of the second switch element 55 becomes the high level or the low level in accordance with the control signal VcL produced by the PWM circuit 51. The first switch element 53 and the second switch element 55 turn ON exclusively, and are controlled not to turn ON simultaneously.

When the first switch element 53 is ON, the electric potential Vlx of the connection point (drive terminal) 57 between the first switch element 53 and the second switch element 55 is the third power supply voltage Vin.

When the second switch element 55 is ON, the electric potential Vlx of the drive terminal 57 is the ground potential 0 V.

The controller 52 makes the first switch element 53 and the second switch element 55 perform switching in accordance with the control signals Vc and VcL produced in the PWM circuit 51 in which the logic amplitude is the second power supply voltage Vs2. The electric potential Vlx of the drive terminal 57 oscillates between the third power supply voltage Vin and the ground potential 0 V.

In the controller 52, since the level shifter 1e has been speeded up, the switching of the first switching element 53 and the second switching element 55 can be speeded up.

A DC-DC converter 60 includes the controller 52, an inductor 61, a smoothing capacitor 62, and a detector 63.

One end of the inductor 61 is connected to the connection point (drive terminal) 57 between the first switch element 53 and the second switch element 55. A voltage Vout obtained by stepping down the third power supply voltage Vin is generated at the other end of the inductor 61.

The smoothing capacitor 62 is connected between the other end of the inductor 61 and the second low potential terminal 10, and smoothes the voltage Vout of the DC-DC converter 60.

The detector 63 is connected between the other end of the inductor 61 and the second low potential terminal 10, and detects the electric potential of the other end of the inductor 61, that is, the voltage Vout of the DC-DC converter 60 and feeds it back to the controller 52.

The PWM circuit 51 of the controller 52 performs PWM control on the first switch element 53 and the second switch element 55 so that the absolute value of the error of a voltage Vfb fed back from the detector 63 may be small.

Next, the operation of the DC-DC converter 60 is described with reference to timing charts.

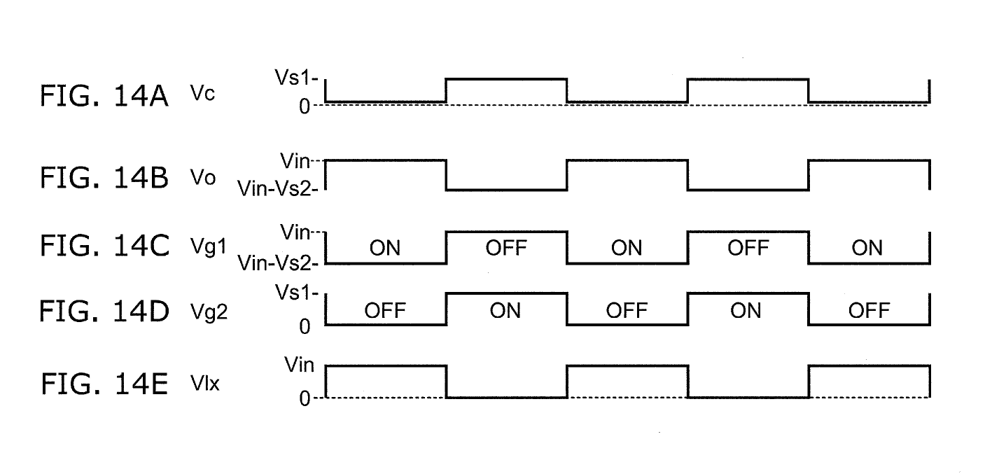

FIGS. 14A to 14E are waveform diagrams of main signals of the DC-DC converter, where FIG. 14A shows the control signal Vc, FIG. 14B shows the output signal Vo of the level shifter, FIG. 14C and FIG. 14D show the gate potentials Vg1 and Vgs of the first and second switch elements, respectively, and FIG. 14E shows the electric potential Vlx of the drive terminal.

In FIG. 14C, the first switch element 53 being controlled to ON or OFF is expressed by ON or OFF, respectively. In FIG. 14D, the second switch element 55 being controlled to ON or OFF is expressed by ON or OFF, respectively.

When the control signal Vc changes from H to L (FIG. 14A), the output signal Vo of the output terminal 8 becomes the high level (FIG. 14B).

The output signal Vo is inverted by the drive circuit 54. The gate potential Vg1 of the first switch element 53 becomes the low level of Vg1=Vin−Vs1, which is lower than the third power supply voltage Vin by an amount of the first power supply voltage Vs1 (FIG. 14C). The first switch element 53 turns ON.

The control signal VcL is in antiphase with the control signal Vc, changes from L to H (not shown), and is inverted by the drive circuit 56. The gate potential Vg2 of the second switch element 55 becomes L of 0 V (FIG. 14D). The second switch element 55 turns OFF.

The electric potential Vlx of the drive terminal 57 becomes the third power supply voltage Vin (FIG. 14E).

A current is supplied to the inductor 61, and the voltage Vout of the DC-DC converter 60 increases.

The error of the voltage Vfb fed back from the detector 63 to the PWM circuit 51 increases, and the PWM circuit 51 changes the control signal Vc into H (FIG. 14A).

When the control signal Vc changes from L to H (FIG. 14A), the output signal Vo of the output terminal 8 becomes the low level (FIG. 14B).

The output signal Vo is inverted by the drive circuit 54. The gate potential Vg1 of the first switch element 53 becomes the high level of the third power supply voltage Vin (FIG. 14C). The first switch element 53 turns OFF.

The control signal VcL is in antiphase with the control signal Vc, changes from H to L (not shown), and is inverted by the drive circuit 56. The gate potential Vg2 of the second switch element 55 becomes H of the second power supply voltage Vs2 (FIG. 14D). The second switch element 55 turns ON.

The electric potential Vlx of the drive terminal 57 becomes the ground potential 0 V (FIG. 14E).

A regenerative current flows through the inductor 61 via the second switch element 55, and the voltage Vout of the DC-DC converter 60 decreases.

The error of the voltage Vfb fed back from the detector 63 to the PWM circuit 51 decreases, and the PWM circuit 51 changes the control signal Vc into L (FIG. 14A).

Similar operations are repeated in the next and subsequent cycles.

Thus, the PWM circuit 51 performs PWM control on the first switch element 53 and the second switch element 55 using the control signals Vc and VcL so that the absolute value of the error of the voltage Vfb fed back may be small.

In the DC-DC converter 60, the level shifter 1e of the controller 52 can transmit the control signal Vc to the first switch element 53 rapidly. Consequently, the switching of the first switch element 53 and the second switch element 55 can be speeded up.

FIG. 13 illustrates the configurations of the controllers 50 and 52 and the DC-DC converter 60 using the level shifter 1e. However, also the level shifters 1, 1a, 1b, and 1d may be used.

Furthermore, it is also possible to use the level shifter 1c shown in FIG. 6 to configure the first switch element 53 as the low side switch and the second switch element 55 as the high side switch.

FIG. 13 illustrates the configurations of the first switch element 53 formed of a PMOS, the second switch element 55 formed of an NMOS, and the drive circuits 54 and 56 formed of an INV. However, the first switch element 53 may be formed of an NMOS. Furthermore, the drive circuits 54 and 56 may be formed of a buffer in which the input signal and the output signal are in phase.

As described with reference to FIG. 13 and FIGS. 14A to 14E, in the controller and the DC-DC converter according to the fourth embodiment, an output signal Vo that has level-shifted by making an quick response to a change of the control signal Vc can be produced to allow high-speed switching without reducing the power efficiency in the steady state. Thus, the controller and the DC-DC converter according to the fourth embodiment can perform high-speed operation with low power consumption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A level shifter comprising:
a current generator connected between a first high potential terminal and a first low potential terminal and configured to generate a first current at a first output line;
a current switch connected between a second high potential terminal and a second low potential terminal, the current switch configured to receive the first current with a higher current supply capacity than the current generator and pass the first current or cut off the first current in accordance with an input signal; and
a protection circuit connected to the first output line between the current generator and the current switch, the protection circuit configured to limit an electric potential of the first output line to not less than an electric potential of the first low potential terminal and not more than an electric potential of the first high potential terminal.

2. The level shifter according to claim 1, wherein the current switch makes an electric potential of an output terminal of the current generator a low level or a high level higher than the low level.

3. The level shifter according to claim 1, wherein
an electric potential of the first high potential terminal is not less than an electric potential of the second high potential terminal, and
the protection circuit limits an electric potential of the first output line to which the current generator outputs the first current to not less than an electric potential of the first low potential terminal.

4. The level shifter according to claim 1, wherein the current switch includes a current mirror.

5. The level shifter according to claim 1, wherein the current generator includes a resistor connected between the first high potential terminal and the first low potential terminal.

6. The level shifter according to claim 1, wherein
an electric potential of the second high potential terminal is not less than an electric potential of the first high potential terminal and
the protection circuit limits an electric potential of the first output line to which the current generator outputs the first current to not more than an electric potential of the first high potential terminal.

7. The level shifter according to claim 1, wherein
the current generator includes:
a second output line configured to generate and output a second current;
a first transistor connected between the first high potential terminal or the first low potential terminal and the first output line and configured to turn ON or OFF in accordance with an electric potential of the second output line; and
a second transistor connected between the first high potential terminal or the first low potential terminal and the second output line and configured to turn ON or OFF in accordance with an electric potential of the first output line,
the current switch further receives the second current, the current switch passes the first current and cuts off the second current or the current switch cuts off the first current and passes the second current in accordance with an input signal, and
the protection circuit limits an electric potential of the second output line to not less than an electric potential of the first low potential terminal and not more than an electric potential of the first high potential terminal.

8. The level shifter according to claim 7, wherein
the first transistor turns OFF after a specified period from when it has turned ON in accordance with an electric potential of the second output line and
the second transistor turns OFF after the specified period from when it has turned ON in accordance with an electric potential of the first output line.

9. The level shifter according to claim 7, wherein
the first transistor connected between the first high potential terminal and the second output line turns ON when an electric potential of the second output line is a low level and
the second transistor connected between the first high potential terminal and the first output line turns ON when an electric potential of the first output line is a low level.

10. A controller comprising:
a level shifter including:
a current generator connected between a first high potential terminal and a first low potential terminal and configured to generate a first current at a first output line;
a current switch connected between a second high potential terminal and a second low potential terminal and configured to receive the first current with a larger current supply capacity than the current generator and pass the first current or cut off the first current in accordance with an input signal; and
a protection circuit connected to the first output line between the current generator and the current switch and configured to limit an electric potential of the first output line to not less than an electric potential of the first low potential terminal and not more than an electric potential of the first high potential terminal;
a PWM circuit connected between the second high potential terminal and the second low potential terminal and configured to produce a PWM signal as the input signal of the level shifter;
a first switch element connected to the first output line of the level shifter and configured to be controlled to ON or OFF based on an electric potential of the first output line; and
a second switch element connected in series to the first switch element and configured to be controlled to ON or OFF by the PWM circuit.

11. The controller according to claim 10, wherein the current switch makes an electric potential of an output terminal of the current generator a low level or a high level higher than the low level.

12. The controller according to claim 10, wherein
an electric potential of the first high potential terminal is not less than an electric potential of the second high potential terminal, and
the protection circuit limits an electric potential of the first output line to which the current generator outputs the first current to not less than an electric potential of the first low potential terminal.

13. The controller according to claim 10, wherein
an electric potential of the second high potential terminal is not less than an electric potential of the first high potential terminal, and
the protection circuit limits an electric potential of the first output line to which the current generator outputs the first current to not more than an electric potential of the first high potential terminal.

14. The controller according to claim 10, wherein
the current generator includes:
a second output line configured to generate and output a second current;
a first transistor connected between the first high potential terminal or the first low potential terminal and the first output line and configured to turn ON or OFF in accordance with an electric potential of the second output line; and
a second transistor connected between the first high potential terminal or the first low potential terminal and the second output line and configured to turn ON or OFF in accordance with an electric potential of the first output line,
the current switch further receives the second current, the current switch passes the first current and cuts off the second current or the current switch cuts off the first current and passes the second current in accordance with an input signal, and
the protection circuit limits an electric potential of the second output line to not less than an electric potential of the first low potential terminal and not more than an electric potential of the first high potential terminal.

15. The controller according to claim 14, wherein
the first transistor turns OFF after a specified period from when it has turned ON in accordance with an electric potential of the second output line and
the second transistor turns OFF after the specified period from when it has turned ON in accordance with an electric potential of the first output line.

16. The controller according to claim 14, wherein
the first transistor connected between the first high potential terminal and the second output line turns ON when an electric potential of the second output line is a low level and
the second transistor connected between the first high potential terminal and the first output line turns ON when an electric potential of the first output line is a low level.

17. A DC-DC converter comprising:
a controller including:
a level shifter including:
a current generator connected between a first high potential terminal and a first low potential terminal and configured to generate a first current at a first output line;
a current switch connected between a second high potential terminal and a second low potential terminal and configured to receive the first current with a larger current supply capacity than the current generator and pass the first current or cut off the first current in accordance with an input signal; and
a protection circuit connected to the first output line between the current generator and the current switch and configured to limit an electric potential of the first output line to not less than an electric potential of the first low potential terminal and not more than an electric potential of the first high potential terminal;
a PWM circuit connected between the second high potential terminal and the second low potential terminal and configured to produce a PWM signal as the input signal of the level shifter;
a first switch element connected to the first output line of the level shifter and configured to be controlled to ON or OFF based on an electric potential of the first output line; and
a second switch element connected in series to the first switch element and configured to be controlled to ON or OFF by the PWM circuit;
an inductor, one end of the inductor being connected to a connection point between the first switch element and the second switch element;
a smoothing capacitor connected between another end of the inductor and the first low potential terminal or the second low potential terminal; and
a detector connected in parallel to the smoothing capacitor and configured to detect an electric potential of the other end of the inductor and feed it back to the controller.

18. The DC-DC converter according to claim 17, wherein
the current generator includes:
a second output line configured to generate and output a second current;
a first transistor connected between the first high potential terminal or the first low potential terminal and the first output line and configured to turn ON or OFF in accordance with an electric potential of the second output line; and
a second transistor connected between the first high potential terminal or the first low potential terminal and the second output line and configured to turn ON or OFF in accordance with an electric potential of the first output line,
the current switch further receives the second current, the current switch passes the first current and cuts off the second current or the current switch cuts off the first current and passes the second current in accordance with an input signal, and
the protection circuit limits an electric potential of the second output line to not less than an electric potential of the first low potential terminal and not more than an electric potential of the first high potential terminal.

19. The DC-DC converter according to claim 17, wherein
the first transistor turns OFF after a lapse of a specified period from when it has turned ON in accordance with an electric potential of the second output line and
the second transistor turns OFF after a lapse of the specified period from when it has turned ON in accordance with an electric potential of the first output line.

20. The DC-DC converter according to claim 17, wherein
the first transistor is connected between the first high potential terminal and the second output line and is ON when an electric potential of the second output line is a low level and
the second transistor is connected between the first high potential terminal and the first output line and is ON when an electric potential of the first output line is a low level.
